(19) United States
(12) Patent Application Publication
(10) Pub. No.: US 2020/0088771 A1
(43) Pub. Date: Mar. 19, 2020

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Takayuki KAROUJI, Tokyo (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 16/282,615

(22) Filed: Feb. 22, 2019

(30) Foreign Application Priority Data
Sep. 14, 2018 (JP) 2018-172629

(51) Int. Cl. G01R 19/165; H03K 5/24; H03K 5/135; H03K 4/06

(52) U.S. Cl. CPC G01R 19/16576; H03K 5/24; H03K 19/20; H03K 4/06; H03K 5/135

(57) ABSTRACT

According to an embodiment, a semiconductor device includes a comparator and a first circuit. The comparator includes a first input terminal and a second input terminal, and is configured to receive a first voltage at the first input terminal and receive at the second input terminal a second voltage that continuously increases or decreases in a first period. The second voltage is equal in magnitude to the first voltage at a first timing in the first period. The first circuit is configured to change a signal to be output, if a second timing at which an output signal from the comparator is switched is out of a second period including the first timing.

### CROSS-REFERENCE TO RELATED APPLICATIONS

This application is based upon and claims the benefit of priority from Japanese Patent Application No. 2018-172629, filed Sep. 14, 2018, the entire contents of which are incorporated herein by reference.

### FIELD

The embodiments described herein relate to semiconductor devices.

### BACKGROUND

For a product that requires functional safety, a comparator is used to make a diagnosis by which a malfunction of a built-in function to be monitored is detected.

### BRIEF DESCRIPTION OF THE DRAWINGS

FIG. 1 is a block diagram showing an example of an overall configuration of a system including a semiconductor device according to a first embodiment;

FIG. 2 is a diagram showing an example of a circuit configuration of the semiconductor device of the first embodiment;

FIG. 3A, FIG. 3B, FIG. 4A, and FIG. 4B are timing charts showing an example of how various signals used in the operation of the semiconductor device of the first embodiment vary with time;

FIG. 5 is a diagram showing an example of a circuit configuration of a semiconductor device according to a comparison example of the first embodiment;

FIG. 6A and FIG. 6B are timing charts showing an example of how various signals used in the operation of the semiconductor device of the comparison example of the first embodiment vary with time;

FIG. 7 is a diagram showing an example of a circuit configuration of a semiconductor device according to a second embodiment;

FIG. 8 is a diagram showing an example of a circuit configuration of a semiconductor device according to a third embodiment;

FIG. 9A and FIG. 9B are timing charts showing an example of how various signals used in the operation of the semiconductor device of the third embodiment vary with time;

FIG. 10 is a diagram showing an example of a circuit configuration of a semiconductor device according to a fourth embodiment;

FIG. 11 is a diagram showing an example of a circuit configuration of a semiconductor device according to fifth embodiment; and

FIG. 12 is a timing chart showing an example of how various signals used in the operation of the semiconductor device of the fifth embodiment vary with time.

### DETAILED DESCRIPTION

Generally, according to an embodiment, a semiconductor device includes a comparator and a first circuit. The comparator includes a first input terminal and a second input terminal, and is configured to receive a first voltage at the first input terminal and receive at the second input terminal a second voltage that continuously increases or decreases in a first period. The second voltage is equal in magnitude to the first voltage at a first timing in the first period. The first circuit is configured to change a signal to be output, if a second timing at which an output signal from the comparator is switched is out of a second period including the first timing.

Embodiments will be described with reference to the accompanying drawings. In the descriptions below, structural elements having similar functions and configurations will be denoted by the same reference symbols or numerals. To distinguish a plurality of structural elements having common reference symbols or numerals, suffixes will be attached to the common reference symbols or numerals. Where the structural elements do not have to be distinguished particularly, only the common reference symbols or numerals will be used, and no suffixes will be attached.

### First Embodiment

In the above-mentioned diagnosis of a function to be monitored, a comparator is used to detect whether or not the function to be monitored is operating within a preset voltage range. For this detection, the function to be monitored is connected to the first input terminal of the comparator, a threshold voltage is applied to the second input terminal of the comparator, and an output signal which is output from the comparator and which indicates the result of the comparison between the voltages applied to the two input terminals is monitored. At this time, “threshold failure” may occur in which the output signal switches between the high (H) level and the low (L) level though the voltage applied to the first input terminal is higher or lower than the threshold voltage.

The first embodiment relates to a semiconductor device capable of detecting such a threshold failure of the comparator.

<1-1> Configuration

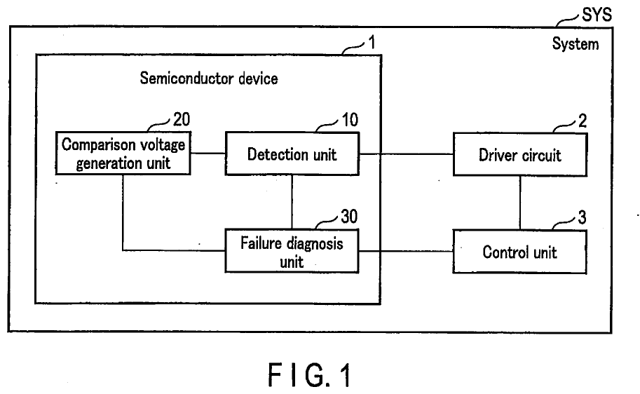

FIG. 1 is a block diagram showing an example of an overall configuration of a system SYS including the semiconductor device 1 according to the first embodiment.

The system SYS includes the semiconductor device 1, a driver circuit 2, and a control unit 3. The system SYS may be, for example, a movable body, such as a vehicle. In this specification, each of the units described as the components included in a system or apparatus may be implemented as either hardware or software, or a combination of hardware and software.

The semiconductor device 1 includes a detection unit 10 including a comparator, a comparison voltage generation unit 20, and a failure diagnosis unit 30.

The detection unit 10 is connected to the driver circuit 2 including a function to be monitored. By using the detection unit 10, the semiconductor device 1 can detect whether or not the function to be monitored in the driver circuit 2 is operating within a preset voltage range and therefore detect a failure of the function to be monitored. For example, a signal output from the detection unit 10 is transferred via the failure diagnosis unit 30 to the control unit 3 that controls, for example, the driver circuit 2. The driver circuit 2 drives, for example, other circuits inside or outside of the system SYS. Note that reference will be made to an example in which the system SYS includes driver circuit 2 and the semiconductor device 1 detects a failure of the function to be monitored in the driver circuit 2. However, the semiconductor device 1 may be configured to detect a failure of a function to be monitored in any other circuit in the system SYS.

The detection unit 10 is capable of receiving a voltage from the comparison voltage generation unit 20, and is operable on the received voltage. The failure diagnosis unit 30 diagnoses the threshold failure of the comparator of the detection unit 10, based on a signal output from the detection unit 10.

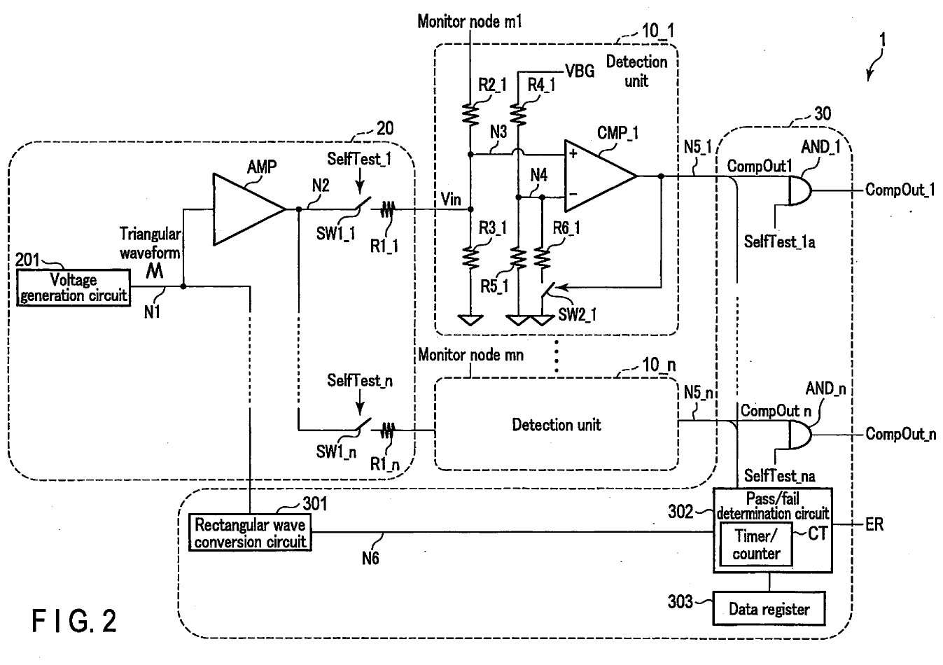

FIG. 2 is a diagram showing an example of a circuit configuration of the semiconductor device 1 according to the first embodiment. FIG. 2 shows an example in which the detection unit 10 of the semiconductor device 1 includes one or more detection units 10_1, . . . , 10_n.

First, the configuration of the comparison voltage generation unit 20 will be described.

The comparison voltage generation unit 20 includes a voltage generation circuit 201, a buffer amplifier AMP, switches SW1_1, . . . , SW1_n, and resistor elements R1_1, . . . , R1_n.

The voltage generation circuit 201 generates a triangular wave voltage and outputs the generated triangular wave voltage on the output terminal. The output terminal of the voltage generation circuit 201 is connected to node N1. The triangular wave voltage is a “VT-proportional wave voltage” that repeats voltage rise of a certain period and voltage fall of a certain period.

The input terminal of buffer amplifier AMP is connected to node N1. The buffer amplifier AMP receives the triangular wave voltage via node N1, amplifies the received triangular wave voltage, and outputs the amplified triangular wave voltage on the output terminal. The output terminal of the buffer amplifier AMP is connected to node N2.

The first terminals of switches SW1_1, . . . , SW1_n are connected to node N2. Switches SW1_1, . . . , SW1_n are associated in one to one correspondence with detection units 10_1, . . . , 10_n, respectively. Also, resistor elements R1_1, . . . , R1_n are associated in one to one correspondence with detection units 10_1, . . . , 10_n, respectively. For example, switch SW1_1 is associated with detection unit 10_1, and resistor element R1_1 is also associated with detection unit 10_1.

The second terminals of switches SW1_1, . . . , SW1_n are connected to the first terminals of those resistor elements which are included among the resistor elements R1_1, . . . , R1_n and which are associated with the same detection unit. The second terminals of resistor elements R1_1, . . . , R1_n are connected to the associated ones of the detection units 10_1, . . . , 10_n. For example, the second terminal of switch SW1_1 is connected to the first terminal of resistor element R1_1, and the second terminal of resistor element R1_1 is connected to node N3 to which the non-inverting input terminal of comparator CMP_1 of detection unit 10_1 is connected.

Each of switches SW1_1, . . . , SW1_n is, for example, a transistor, and the switching between the ON state and the OFF state is controlled by control signals SelfTest_1, . . . , SelfTest_n supplied to the gates of the respective switches. Each of switches SW1_1, . . . , SW1_n functions as a switch for selecting whether or not to supply the triangular wave voltage to the associated detection unit. For example, when switch SW1_1 is in the ON state, the triangular wave voltage applied to node N2 is applied to node N3 after being dropped by resistor element R1_1. When switch SW1_1 is in the OFF state, node N2 and resistor element R1_1 are disconnected from each other, so that the triangular wave voltage is not applied to node N3.

By turning on and off switches SW1_1, . . . , SW1_n, the detection units associated with the switches switch between the function monitoring mode and the comparator diagnosis mode, which will be described later.

Next, configurations of detection units 10_1, . . . , 10_n will be described in detail.

In the description set forth below, detection unit 10_1 will be mentioned as an example, but the other detection units have the same configuration as detection unit 10_1.

Detection unit 10_1 includes comparator CMP_1, resistor elements R2_1, R3_1, R4_1, R5_1 and R6_1, and switch SW2_1.

The first terminal of resistor element R2_1 is connected to monitor node m1, and the second terminal of the resistor element R2_1 is connected to node N3 described above. The monitor node m1 is selectively connected to a function that is to be monitored in the driver circuit 2.

The first terminal of resistor element R3_1 is connected to node N3, and the second terminal of resistor element R3_1 is grounded.

The first terminal of resistor element R4_1 is connected to a voltage source VBG, and the second terminal of resistor element R4_1 is connected to node N4.

The first terminal of resistor element R5_1 is connected to node N4, and the second terminal of resistor element R5_1 is grounded.

The first terminal of resistor element R6_1 is connected to node N4, and the second terminal of resistor element R6_1 is connected to the first terminal of switch SW2_1. The second terminal of switch SW2_1 is grounded, and the gate of switch SW2_1 is connected to node N5_1. Switch SW2_1 is, for example, a transistor.

The non-inverting input terminal (+) of comparator CMP_1 is connected to node N3, the inverting input terminal (−) of comparator CMP_1 is connected to node N4, and the output terminal of the comparator CMP_1 is connected to node N5_1. For example, the output terminals of detection units 10_1, . . . , 10_n are connected to different nodes.

Comparator CMP_1 compares the voltage applied to the non-inverting input terminal with the voltage applied to the inverting input terminal, and outputs an output signal CompOut1 indicating the result of the comparison from the output terminal of comparator CMP_1. For example, if the output signal CompOut 1 is at the L level, this indicates that the voltage applied to the non-inverting input terminal is lower than the voltage applied to the inverting input terminal. On the other hand, for example, if the output signal CompOut 1 is at the H level, this indicates that the voltage applied to the non-inverting input terminal is higher than the voltage applied to the inverting input terminal. Where the threshold failure occurs in comparator CMP_1, the magnitude relation indicated by output signal CompOut1 does not necessarily agree with the magnitude relation between the voltage applied to the non-inverting input terminal and the voltage applied to the inverting input terminal.

Finally, a configuration of the failure diagnosis unit 30 will be described. By the failure diagnosis unit 30, a diagnosis of the above-described threshold failure can be executed for the comparator included in a detection unit that is in the comparator diagnosis mode.

The failure diagnosis unit 30 includes a rectangular wave conversion circuit 301, a pass/fail determination circuit 302, a data register 303, and AND circuits AND_1, . . . , AND_N.

The input terminal of the rectangular wave conversion circuit 301 is connected to node N1, and the output terminal of the rectangular wave conversion circuit 301 is connected to node N6.

The first input terminal of the pass/fail determination circuit 302 is connected to node N6, and the second input terminal of the pass/fail determination circuit 302 is connected to an n-bit signal line that can reflect output signals from the detection units. In the n-bit signal line, the wiring of each one bit reflects an output signal from the comparator included in one of the detection units 10_1, . . . , 10_n. The first output terminal of the pass/fail determination circuit 302 is connected to the data register 303. The pass/fail determination circuit 302 includes a timer/counter CT.

Each of AND circuits AND_1, . . . , AND_n is associated in one to one correspondence with one of the detection units 10_1, . . . , 10_n. The first input terminals of the AND circuits AND_1, . . . , AND_n are connected to associated ones of the detection units 10_1, . . . , 10_n. For example, the first input terminal of AND circuit AND_1 is connected to node N5_1 to which the output terminal of comparator CMP_1 of detection unit 10_1 is connected. Control signals SelfTest_1a, . . . , SelfTest_na are supplied to the second input terminals of AND circuits AND_1, . . . , AND_n, respectively. The output terminals of AND circuits AND_1, . . . , AND_n are connected to the control unit 3, for example.

A triangular wave voltage generated by the voltage generation circuit 201 is supplied via node N1 to the rectangular wave conversion circuit 301. The rectangular wave conversion circuit 301 converts the supplied triangular wave voltage into a rectangular wave signal and supplies the converted rectangular wave signal to the pass/fail determination circuit 302. For example, the rectangular wave signal falls from the H level to the L level at the time when the triangular wave voltage becomes minimum, and rises from the L level to the H level at the time when the triangular wave voltage becomes maximum. Hereinafter, the case where the rectangular wave signal behaves in the this manner will be described by way of example, but the condition of the triangular waveform under which the rectangular wave signal rises and the condition of the triangular waveform under which the rectangular wave signal falls may be different from those described above. The rectangular wave signal is supplied to the timer/counter CT of the pass/fail determination circuit 302.

The timer/counter CT of the pass/fail determination circuit 302 generates a clock signal, counts the periods of the clock signal, and holds the count result as a timer/counter value. The pass/fail determination circuit 302 receives output signals CompOut1, . . . , CompOutn from detection units 10_1, . . . , 10_n through the n-bit signal line. The pass/fail determination circuit 302 determines whether the comparators in the detection units 10_1, . . . , 10_n work properly or not, by using the timer/counter value and output signals CompOut1, . . . , CompOutn. In the pass/fail determination for the comparators, a determination is made as to whether or not a threshold failure occurs in the comparators.

The pass/fail determination circuit 302 transfers the latched timer/counter value to the data register 303, and the data register 303 fetches the transferred timer/counter value.

<1-2> Operation

Next, a description will be given of an operation of the semiconductor device 1.

Each of the detection units 10_1, . . . , 10_n can operate in the above-mentioned two modes. One of the modes is a function monitoring mode, and the other mode is a comparator diagnosis mode. In the description set forth below, detection unit 10_1 will be mentioned as an example, but the other detection units operate in the same manner as detection unit 10_1.

In the function monitoring mode, detection unit 10_1 operates such that the voltage which is applied to the corresponding monitor node m1 and on which a function to be monitored is operating is monitored. In the comparator diagnosis mode, detection unit 10_1 operates such that comparator CMP_1 of detection unit 10_1 is diagnosed. The mode of detection unit 10_1 is switched from one to the other by turning on or off the associated switch SW1_1. When switch SW1_1 is OFF, detection unit 10_1 is in the function monitoring mode. When switch SW1_1 is ON, detection unit 10_1 is in the comparator diagnosis mode. This holds true of the other detection units as well.

<1-2-1> Operation in Function Monitoring Mode

In the function monitoring mode, switch SW1_1 is in the OFF state as described above. For this reason, the non-inverting input terminal of comparator CMP_1 is applied with voltage Vin obtained by dividing a voltage which is applied to monitor node m1 and on which the function to be monitored is operating by resistor element R2_1 and resistor element R3_1.

Also, as described above, the output terminal of comparator CMP_1 is connected to node N5_1, and switch SW2_1 is connected to node N5_1. Therefore, for example, when output signal CompOut1 is at the L level, switch SW2_1 is in the OFF state, and when the output signal CompOut1 is at the H level, switch SW2_1 is in the ON state.

When output signal CompOut1 is at the L level, that is, when switch SW2_1 is in the OFF state, a voltage obtained by dividing the voltage from voltage source VBG by the resistance of resistor element R4_1 and the resistance of resistor element R5_1 is applied to the inverting input terminal of comparator CMP_1.

When output signal CompOut1 is at the H level, that is, when switch SW2_1 is in the ON state, a voltage obtained by dividing the voltage from voltage source VBG by the resistance of resistor element R41, and the combined resistance of resistor elements R5_1 and R6_1 is applied to the inverting input terminal of comparator CMP_1. Since the combined resistance of resistor elements R5_1 and R6_1 is smaller than the resistance of resistor element R5_1, the voltage applied to the inverting input terminal of comparator CMP_1 is low, as compared with the voltage applied when switch SW2_1 is in the OFF state.

As described above, when the voltage applied to the non-inverting input terminal is lower than the voltage applied to the inverting input terminal and output signal CompOut1 is therefore at the L level, a higher voltage (an H level threshold voltage) is applied to the inverting input terminal. On the other hand, when the voltage applied to the non-inverting input terminal is higher than the voltage applied to the inverting input terminal and output signal CompOut1 is therefore at the H level, a lower voltage (an L level threshold voltage) is applied to the inverting input terminal.

Therefore, output signal CompOut 1 rises from the L level to the H level when the voltage applied to the non-inverting input terminal becomes higher than the H level threshold voltage. On the other hand, output signal CompOut1 falls from the H level to the L level when the voltage applied to the non-inverting input terminal becomes lower than the L level threshold voltage. Accordingly, the semiconductor device 1 can detect that the voltage applied to the non-inverting input terminal becomes higher than the H level threshold voltage or lower than the L level threshold voltage.

In the function monitoring mode, it can be detected based on output signal CompOut1 whether or not the function to be monitored is operating within a preset voltage range defined by the H level threshold voltage and the L level threshold voltage. This enables detection of a failure in which a function to be monitored is not operating within the voltage range.

<1-2-2> Operation in Comparator Diagnosis Mode

In the comparator diagnosis mode, switch SW1_1 is in the ON state as described above. Therefore, voltage Vin, which is determined by resistor elements R1_1, R2_1 and R3_1 and a triangular wave voltage applied to node N2 by buffer amplifier AMP, is applied to the non-inverting input terminal of comparator CMP_1.

The timer/counter CT starts time measurement based on the timer/counter value, for example, with the time at which the rectangular wave signal supplied from the rectangular wave conversion circuit 301 falls from the H level to the L level as a first measurement start time. Thereafter, the timer/counter CT latches the timer/counter value obtained at the time when voltage Vin gradually rises and output signal CompOut1 rises from the L level to the H level. Further, the timer/counter CT starts time measurement based on the timer/counter value, for example, with the time at which the rectangular wave signal rises from the L level to the H level as a second measurement start time. Thereafter, the timer/counter CT latches the timer/counter value obtained at the time when voltage Vin gradually falls and output signal CompOut1 falls from the H level to the L level.

Next, the pass/fail determination circuit 302 executes the pass/fail determination based on the latched timer/counter values. Specifically, the pass/fail determination circuit 302 determines whether or not the timer/counter value latched on the basis of the first measurement start time is within a “first OK range.” The first OK range corresponds to an allowable period of time in which it can be determined that, for example, comparator CMP_1 does not undergo a threshold failure, and which includes a timing at which gradually increasing voltage Vin becomes equal to the H level threshold voltage. Also, the pass/fail determination circuit 302 determines whether or not the timer/counter value latched on the basis of the second measurement start time is within a “second OK range.” The second OK range corresponds to an allowable period of time in which it can be determined that, for example, comparator CMP_1 does not undergo a threshold failure, and which includes a timing at which gradually decreasing voltage yin becomes equal to the L level threshold voltage.

The times from the first measurement start time to the lower limit and upper limit of the first OK range and the times from the second measurement start time to the lower limit and upper limit of the second OK range are predetermined by the pass/fail determination circuit 302, for example, based on the triangular wave voltage generated by the voltage generation circuit 201, the amplification degree of the buffer amplifier AMP, resistor elements R1_1, R2_1 and R3_1, the H level threshold voltage and L level threshold voltage of comparator CMP_1.

The time from the lower limit to the upper limit of the first OK range may be, for example, a time necessary for the voltage Vin to increase by a difference in potential obtained by multiplying a difference between the H level threshold voltage and the L level threshold voltage by a preset coefficient. The time from the lower limit to the upper limit of the second OK range may be, for example, a time necessary for the voltage Vin to decrease by a difference in potential obtained by multiplying a difference between the H level threshold voltage and the L level threshold voltage by a preset coefficient.

The pass/fail determination circuit 302 outputs signal ER at the L level from the second output terminal of the pass/fail determination circuit 302, where the pass/fail determination circuit 302 determines that the timer/counter value latched on the basis of the first measurement start time is within the first OK range or that the timer/counter value latched on the basis of the second measurement start time is within the second OK range. On the other hand, the pass/fail determination circuit 302 outputs signal ER at the H level from the second output terminal, where the pass/fail determination circuit 302 determines that the timer/counter value latched on the basis of the first measurement start time is not within the first OK range or that the timer/counter value latched on the basis of the second measurement start time is not within the second OK range. The fact that signal ER is at the H level indicates that the voltage that can be regarded as being actually compared in comparator CMP_1 is outside the allowable range described above and that comparator CMP_1 is determined to undergo a threshold failure.

Selections of the first OK range and the second OK range by the pass/fail determination circuit 302 is based on, for example, control signals supplied to switches associated with detection units and based on whether the rectangular wave signal has fallen or risen. For example, the pass/fail determination circuit 302 detects that control signal SelfTest_1 supplied to switch SW1_1 associated with detection unit 10_1 is at the H level and that the rectangular wave signal has fallen from the H level to the L level, and based on this detection, the pass/fail determination circuit 302 selects the first OK range, which is set to be used for the diagnosis of the threshold failure of comparator CMP_1 of detection unit 10_1. Also, the pass/fail determination circuit 302 detects that control signal SelfTest_1 is at the H level and that the rectangular wave signal has risen from the L level to the H level, and based on this detection, the pass/fail determination circuit 302 selects the second OK range, which is set to be used for the diagnosis of the threshold failure of comparator CMP_1 of detection unit 10_1.

It should be noted that the H level threshold voltage and/or the L level threshold voltage may be set to be different values for the comparators in the respective detection units. In this case, the resistance values of the resistor elements which are among resistor elements R1_1, . . . , R1_n and which are associated with respective detection units may be designed such that at least either of the timings at which the gradually increasing input voltages applied to the non-inverting input terminals of the comparators become equal to the H level threshold voltages or the timings at which the gradually decreasing input voltages applied to the non-inverting input terminals become equal to the L level threshold voltages are concurrent. Further, the comparators may be designed such that the first OK ranges and/or the second OK ranges match.

In addition, the pass/fail determination circuit 302 may calculate, based on the timer/counter value latched on the basis of the first measurement start time or second measurement start time, a voltage which can be regarded as being actually compared in the comparator CMP_1, a difference between the voltage which can be regarded as being actually compared in the comparator CMP_1 and the H level threshold voltage or L level threshold voltage, and a difference between the voltage which can be regarded as being actually compared in the comparator CMP_1 and a voltage corresponding to the first OK range or the second OK range.

As described above, timer/counter values are fetched into the data register 303. Therefore, the voltage that can be regarded as being actually compared in the comparator CMP_1 can be monitored by use of a communication device (not shown), and a determination can be made by an apparatus external to the semiconductor device 1.

In addition, where a threshold failure of comparator CMP_1 of detection unit 10_1 is diagnosed, it is possible to control whether or not to notify the control unit 3. For example, where control signal SelfTest_1a is at the H level, output signal CompOut_1 is output from the output terminal of AND circuit AND_1 such that it has the same logic level as output signal CompOut1 from comparator CMP_1. On the other hand, where control signal SelfTest_1a is at the L level, output signal CompOut_1 is output at the L level from the output terminal of AND circuit AND_1.

The above operation will be described in order of time with reference to timing charts.

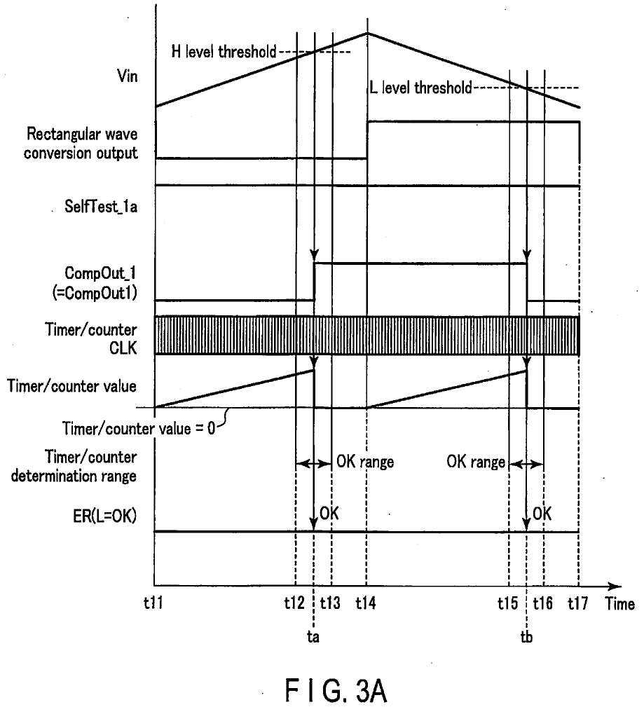

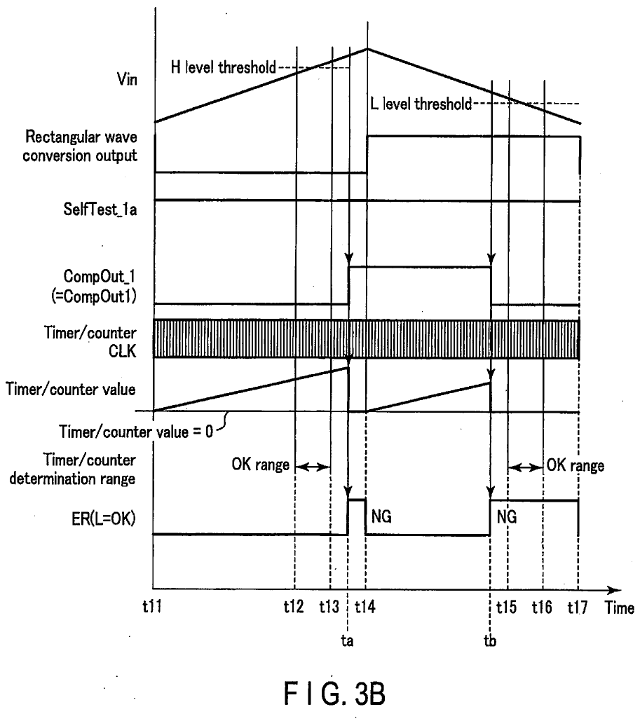

FIGS. 3A and 3B are timing charts showing an example of how various signals used in the operation of the semiconductor device 1 of the first embodiment vary with time. Note that the timing charts shown in FIGS. 3A and 3B are an example of the timing charts of the case where switch SW1_1 is turned on and threshold failure of comparator CMP_1 is diagnosed based on output signal CompOut1 supplied from comparator CMP_1 of detection unit 10_1. By causing AND circuit AND_1 associated with detection unit 10_1 to receive control signal SelfTest_1a at the H level, output signal CompOut_1 is output from the output terminal of AND circuit AND_1 at the same logic level as output signal CompOut1 and is supplied, for example, to the control unit 3.

Voltage Vin applied to the non-inverting input terminal of comparator CMP_1 has a triangular waveform, and voltage Vin increases monotonically from time t11 to time t14. The rectangular wave signal supplied from the rectangular wave conversion circuit 301 to the pass/fail determination circuit 302 falls from the H level to the L level at time t11, and maintains the L level until time t14.

In the pass/fail determination circuit 302, the timer/counter CT starts time measurement based on the timer/counter value, with time t11 as a first measurement start time. During the period from time t11 to time t14, voltage Vin gradually rises, and output signal CompOut1 supplied from comparator CMP_1 and input to pass/fail determination circuit 302 rises from the L level to the H level at time ta. The timer/counter CT latches the timer/counter value obtained at time ta.

The pass/fail determination circuit 302 executes the pass/fail determination based on the timer/counter value latched on the basis of time tn. Specifically, the pass/fail determination circuit 302 determines whether or not the timer/counter value latched on the basis of time t11 is within the first OK range. The first OK range corresponds to an allowable time period from time t12 to time t13, in which it can be determined that, for example, comparator CMP_1 does not undergo a threshold failure, and which includes a timing at which gradually increasing voltage Vin becomes equal to the H level threshold voltage.

The time period from time t11 to time t12 and the time period from time t11 to time t13 are preset in the pass/fail determination circuit 302. That is, the values that the timer/counter value should be at times t12 and t13 when counting is started at time t11 are stored in the pass/fail determination circuit 302 in advance. Then, the pass/fail determination circuit 302 determines whether or not the timer/counter value latched at time to is within the interval between the timer/counter values corresponding to times t12 and t13.

In the example shown in FIG. 3A, the timer/counter value latched on the basis of time t11 is within the first OK range. Therefore, in response to the determination that the timer/counter value latched on the basis of the time t11 is within the first OK range, the pass/fail determination circuit 302 outputs signal ER at the L level from the second output terminal of the pass/fail determination circuit 302.

Voltage Vin decreases monotonically from time t14 to time t17. The rectangular wave signal rises from the L level to the H level at time t14 and maintains the H level until time t17.

In the pass/fail determination circuit 302, the timer/counter CT starts time measurement based on the timer/counter value, with time t14 as a second measurement start time. During the period from time t14 to time t17, voltage Vin gradually falls, and output signal CompOut1 mentioned above falls from the H level to the L level at time tb. The timer/counter CT latches the timer/counter value obtained at time tb.

The pass/fail determination circuit 302 executes the pass/fail determination based on the timer/counter value latched on the basis of time t14. Specifically, the pass/fail determination circuit 302 determines whether or not the timer/counter value latched on the basis of time t14 is within the second OK range. The second OK range corresponds to an allowable time period from time t15 to time t16, in which it can be determined that, for example, comparator CMP_1 does not undergo a threshold failure, and which includes a timing at which gradually decreasing voltage Vin becomes equal to the L level threshold voltage. The time period from time t14 to time t15 and the time period from time t14 to time t16 are preset in the pass/fail determination circuit 302. That is, the values that the timer/counter value should be at times t15 and t16 when counting is started at time t14 are stored in the pass/fail determination circuit 302 in advance. Then, the pass/fail determination circuit 302 determines whether or not the timer/counter value latched at time tb is within the interval between the timer/counter values corresponding to times t15 and t16.

In the example shown in FIG. 3A, the timer/counter value latched on the basis of time t14 is within the second OK range. Therefore, in response to the determination that the timer/counter value latched on the basis of the time t14 is within the second OK range, the pass/fail determination circuit 302 outputs signal ER at the L level from the second output terminal of the pass/fail determination circuit 302.

On the other hand, in the example shown in FIG. 3B, the timer/counter value latched on the basis of time t11 is not within the first OK range. Therefore, in response to the determination that the timer/counter value latched on the basis of the time t11 is not within the first OK range, the pass/fail determination circuit 302 outputs signal ER at the H level from the second output terminal of the pass/fail determination circuit 302 and keeps outputting that signal until time t14 at which the rectangular wave signal rises from the L level to the H level.

In the example shown in FIG. 3B, the timer/counter value latched on the basis of time t14 is not within the second OK range. Therefore, in response to the determination that the timer/counter value latched on the basis of the time t14 is not within the second OK range, the pass/fail determination circuit 302 outputs signal ER at the H level from the second output terminal of the pass/fail determination circuit 302 and keeps outputting that signal until time t17 at which the rectangular wave signal falls from the H level to the L level.

FIGS. 4A and 4B are timing charts showing another example of how various signals used in the operation of the semiconductor device 1 of the first embodiment vary with time. Note that like the timing charts shown in FIGS. 3A and 3B, the timing charts shown in FIGS. 4A and 4B are an example of the timing charts of the case where switch SW1_1 is turned on and a threshold failure of comparator CMP_1 is diagnosed based on output signal CompOut1 supplied from comparator CMP_1 of detection unit 10_1. By causing AND circuit AND_1 associated with detection unit 10_1 to receive control signal SelfTest_1a at the L level, output signal CompOut_1 from AND circuit AND_1 is supplied, for example, to the control unit 3, with the L level maintained constantly. This control may be performed to make a failure diagnosis of the comparator without notifying the control unit 3 of abnormality, when the system SYS including the semiconductor device 1 is operating normally and the function monitoring by the comparator is unnecessary.

Except that control signal SelfTest1a is constantly at the L level and output signal. CompOut_1 is constantly at the L level, the timing chart shown in FIG. 4A is the same as the timing chart shown in FIG. 3A, and the timing chart shown in FIG. 4B is the same as the timing chart shown in FIG. 3B.

<1-3> Advantages

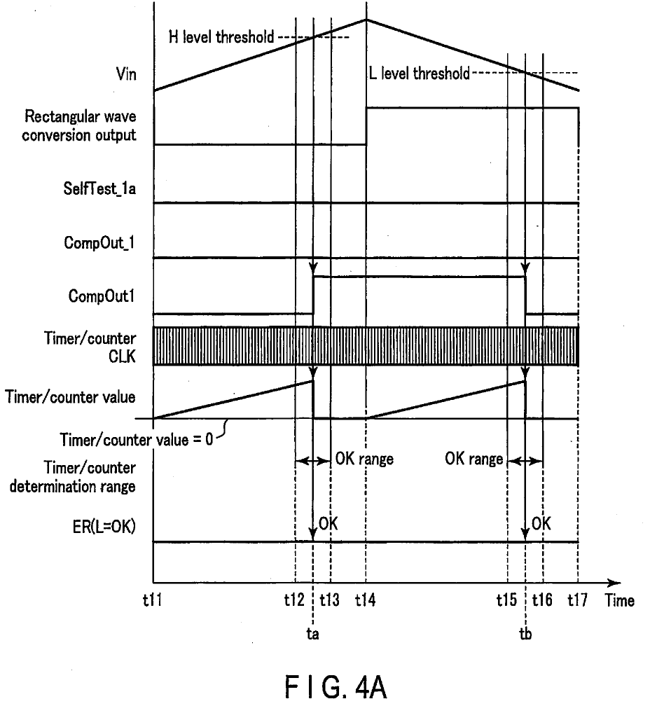

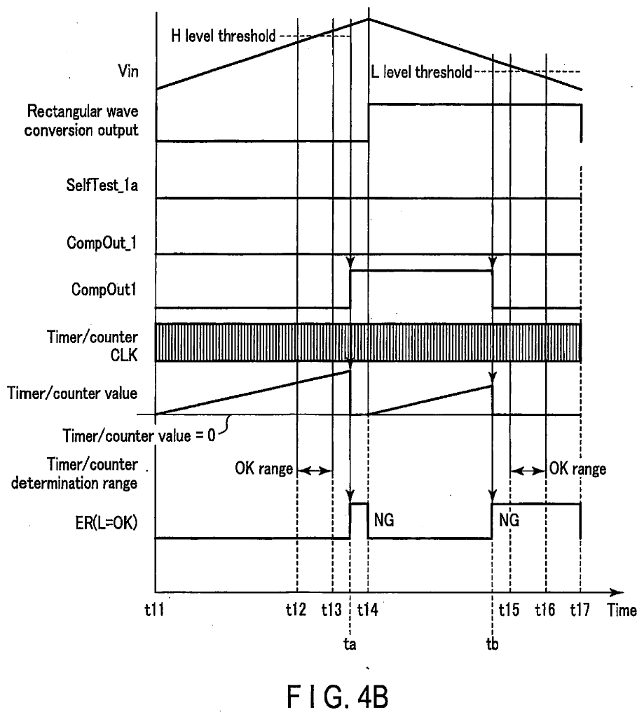

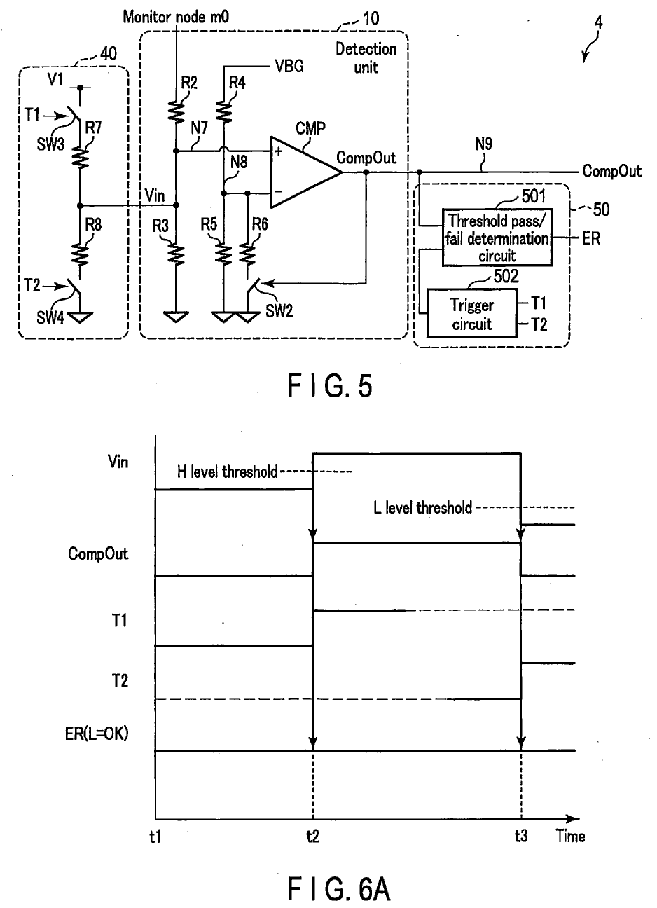

FIG. 5 is a diagram showing an example of a circuit configuration of a semiconductor device 4 according to a comparative example of the first embodiment.

The semiconductor device 4 includes a detection unit 10 including a comparator CMP, and diagnosis units 40 and 50. The semiconductor device 4 can detect a failure of the comparator by using the diagnosis units 40 and 50.

As will be described below, detection unit 10 has the same configuration as detection unit 10_1 detailed above.

Detection unit 10 includes comparator CMP, resistor elements R2, R3, R4, R5 and R6, and switch SW2.

The first terminal of resistor element R2 is connected to monitor node m0, and the second terminal of resistor element R2 is connected to node N7. Monitor node m0 is selectively connected to a function which is to be monitored.

The first terminal of resistor element R3 is connected to node N7, and the second terminal of resistor element R3 is grounded.

The first terminal of resistor element R4 is connected to a voltage source VBG and the second terminal of resistor element R4 is connected to node N8.

The first terminal of resistor element R5 is connected to node NB, and the second terminal of resistor element R5 is grounded.

The first terminal of resistor element R6 is connected to node NB, and the second terminal of resistor element R6 is connected to the first terminal of switch SW2. The second terminal of switch SW2 is grounded, and the gate of switch SW2 is connected to node N9. Switch SW2 is, for example, a transistor.

The non-inverting input terminal of comparator CMP is connected to node N7, the inverting input terminal of comparator CMP is connected to node N8, and the output terminal of the comparator CMP is connected to node N9.

Comparator CMP compares the voltage applied to the non-inverting input terminal with the voltage applied to the inverting input terminal, and outputs an output signal CompOut indicating the result of the comparison from the output terminal of comparator CMP.

As described in detail in connection with detection unit 10_1, the voltage applied to the inverting input terminal of comparator CMP is either the H level threshold voltage or the L level threshold voltage, and the semiconductor device 4 can detect whether the voltage applied to the non-inverting input terminal becomes higher than the H level threshold voltage or lower than the L level threshold voltage.

Diagnosis unit 40 is a circuit that affects the voltage applied to the non-inverting input terminal, and includes a voltage source V1, resistor elements R7 and RB, and switches SW3 and SW4.

The voltage source V1 is connected to the first terminal of switch SW3, and the second terminal of switch SW3 is connected to the first terminal of resistor element R7. The second terminal of resistor element R7 is connected to node N7. Switch SW3 is, for example, a transistor, and the switching between the ON state and the OFF state is controlled by control signal T1 supplied to the gate of switch SW3. For example, when control signal T1 is at the L level, switch SW3 is in the OFF state, and when control signal T1 is at the H level, switch SW3 is in the ON state.

The first terminal of resistor element R8 is connected to node N7 mentioned above, and the second terminal of resistor element R8 is connected to the first terminal of switch. SW4. The second terminal of switch SW4 is grounded. Switch SW4 is, for example, a transistor, and the switching between the ON state and the OFF state is controlled by control signal T2 supplied to the gate of switch SW4. For example, when control signal T2 is at the L level, switch SW4 is in the OFF state, and when control signal T2 is at the H level, switch SW4 is in the ON state.

When switches SW3 and SW4 are in the OFF state, the non-inverting input terminal of comparator CMP is applied with voltage Vin obtained by dividing a voltage which is applied to monitor node m0 and on which the function to be monitored is operating by the resistance of resistor element R2 and the resistance of resistor element R3. As detailed above in connection with detection unit 10_1, it can be detected based on output signal CompOut whether or not the function to be monitored is operating within a preset voltage range defined by the H level threshold voltage and the L level threshold voltage. This enables detection of a failure in which the function to be monitored is not operating within the voltage range. For example, resistor elements R2 and R3 are designed such that voltage Vin applied then is higher than the L level threshold voltage and lower than the H level threshold voltage when the monitored function is operating normally.

When switch SW3 is in the ON state and switch SW4 is in the OFF state, voltage Vin, which is determined by the resistor elements R2, R3, and R7 and a voltage applied by the voltage source V1, is applied to the non-inverting input terminal of comparator CMP. For example, the voltage source V1 and resistor element R7 are designed such that voltage Vin applied then is higher than the H level threshold voltage.

When switches SW3 and SW4 are in the ON state, voltage Vin, which is determined by resistor elements R2, R3, R7 and R8 and a voltage applied by the voltage source V1, is applied to the non-inverting input terminal of comparator CMP. For example, the voltage source V1 and resistor elements R7 and R8 are designed such that voltage Vin applied then is lower than the L level threshold voltage.

Diagnosis unit 50 includes a threshold pass/fail determination circuit 501 and a trigger circuit 502.

The first input terminal of the threshold pass/fail determination circuit 501 is connected to node N9 mentioned above.

Control signal T1 is supplied to the first input terminal of the trigger circuit 502, and control signal T2 is supplied to the second input terminal of the trigger circuit 502. The output terminal of the trigger circuit 502 is connected to the second input terminal of the threshold pass/fail determination circuit 501.

The threshold pass/fail determination circuit 501 receives output signal CompOut supplied from comparator CMP via node N9. In addition, the threshold pass/fail determination circuit 501 receives an output signal from the trigger circuit 502.

Where a failure of a comparator is diagnosed using the diagnosis units 40 and 50, first diagnosis and second diagnosis are performed, for example. In the state where both control signals T1 and T2 are first set at the L level, control signal T1 is changed from the L level to the H level, with control signal T2 kept at the L level. At the time, the first diagnosis is performed. Then, control signal T2 is changed from the L level to the H level, with control signal T1 kept at the H level. At the time, the second diagnosis is performed.

When control signal T1 rises from the L level to the H level, the trigger circuit 502 outputs a first trigger signal indicating the rise of control signal T1 from the output terminal of the trigger circuit 502. When control signal T2 rises from the L level to the H level, the trigger circuit 502 outputs a second trigger signal indicating the rise of control signal T2 from the output terminal of the trigger circuit 502.

In the first diagnosis, the first trigger signal is output from the trigger circuit 502 when control signal T1 is changed from the L level to the H level, as described above. In response to the first trigger signal, the threshold pass/fail determination circuit 501 makes a threshold pass/fail determination based on output signal CompOut supplied from comparator CMP. In the threshold pass/fail determination, the threshold pass/fail determination circuit 501 determines whether or not output signal CompOut rises from the L level to the H level. In response to detection of the switching of output signal CompOut between the L level and the H level, the threshold pass/fail determination circuit 501 outputs signal ER at the L level as a result of the threshold pass/fail determination. On the other hand, in response to failure to detect the switching of output signal CompOut between the L level and the H level, the threshold pass/fail determination circuit 501 outputs signal ER at the H level as a result of the threshold pass/fail determination.

In the second diagnosis, the second trigger signal is output from the trigger circuit 502 when control signal T2 is changed from the L level to the H level, with control signal T1 kept at the H level, as described above. In response to the second trigger signal, the threshold pass/fail determination circuit 501 makes a threshold pass/fail determination based on output signal CompOut. In the threshold pass/fail determination, the threshold pass/fail determination circuit 501 determines whether or not output signal CompOut falls from the H level to the L level. In response to detection of the switching of output signal CompOut between the L level and the H level, the threshold pass/fail determination circuit 501 outputs signal ER at the L level as a result of the threshold pass/fail determination. On the other hand, in response to failure to detect the switching of output signal CompOut between the L level and the H level, the threshold pass/fail determination circuit 501 outputs signal ER at the H level as a result of the threshold pass/fail determination.

The above operation will be described in order of time with reference to timing charts.

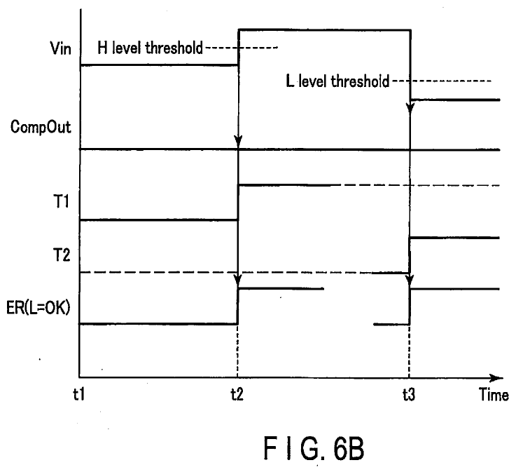

FIGS. 6A and 6B are timing charts showing an example of how various signals used in the operation of the semiconductor device 4 according to the comparative example of the first embodiment vary with time.

During the period from time t1 to time t2, the control signals T1 and T2 maintain the L level. At this time, switches SW3 and SW4 are in the OFF state, and voltage Vin applied to the non-inverting input terminal of comparator CMP is higher than the L level threshold voltage and is lower than the H level threshold voltage.

At time t2, control signal T1 is changed from the L level to the H level, with control signal T2 maintained at the L level. At this time, switch SW3 is in the ON state and switch SW4 is in the OFF state, and as described above, voltage Vin becomes higher than the H level threshold voltage. When control signal T1 is changed from the L level to the H level, the first trigger signal output from the trigger circuit 502 is supplied to the second input terminal of the threshold pass/fail determination circuit 501. In response to the first trigger signal, the threshold pass/fail determination circuit 501 makes a threshold pass/fail determination based on output signal CompOut supplied from comparator CMP.

In the example shown in FIG. 6A, the threshold pass/fail determination circuit 501 detects that output signal CompOut from comparator CMP rises from the L level to the H level at time t2; In response to detection of the switching of output signal CompOut between the L level and the H level, the threshold pass/fail determination circuit 501 outputs signal ER at the L level as a result of the threshold pass/fail determination.

At time t3, control signal T2 is changed from the L level to the H level, with control signal T1 maintained at the H level. At this time, switches SW3 and SW4 are in the ON state, and as described above, voltage Vin becomes lower than the L level threshold voltage. At this time, the second trigger signal output from the trigger circuit 502 is supplied to the second input terminal of the threshold pass/fail determination circuit 501. In response to the second trigger signal, the threshold pass/fail determination circuit 501 makes a threshold pass/fail determination based on output signal CompOut.

In the example shown in FIG. 6A, the threshold pass/fail determination circuit 501 detects that output signal CompOut falls from the H level to the L level at time t3. In response to detection of the switching of output signal CompOut between the L level and the H level, the threshold pass/fail determination circuit 501 outputs signal ER at the L level as a result of the threshold pass/fail determination.

On the other hand, in the example shown in FIG. 6B, the threshold pass/fail determination circuit 501 does not detect that output signal CompOut switches between the L level and the H level at time t 2. In response to failure to detect the switching of output signal CompOut between the L level and the H level, the threshold pass/fail determination circuit 501 outputs signal ER at the H level as a result of the threshold pass/fail determination.

In the example shown in FIG. 6B, the threshold pass/fail determination circuit 501 does not detect switching of output signal CompOut between the L level and the H level at time t3. In response to failure to detect the switching of output signal CompOut between the L level and the H level, the threshold pass/fail determination circuit 501 outputs signal ER at the H level as a result of the threshold pass/fail determination.

As described above, the semiconductor device 4 shown in FIG. 5 applies the threshold voltages to the first input terminal of comparator CMP, and at the same time controls the voltage applied to the second input terminal of comparator CMP such that it is higher than H level threshold voltage or lower than the L level threshold voltage. When controlling the voltage applied to the second input terminal in this manner, the semiconductor device 4 can diagnose whether the operation of the comparator for switching the output signal between the H level and the L level (which is referred to as “I/O switching operation” herein) is performed normally or not, based on the detection of whether or not output signal CompOut from comparator CMP switches between the L level and the H level. When the switching of output signal CompOut is not detected, the semiconductor device 4 can determine that something is wrong with the I/O switching operation of comparator CMP.

However, the semiconductor device 4 can only determine whether or not the output of comparator CMP is inverted under the inversion-enabled condition. For this reason, it is not possible to determine how the threshold voltages of comparator CMP is. That is, in the threshold failure diagnosis by the semiconductor device 4, it is only possible to determine whether or not comparator CMP has the designed H level threshold and/or L level threshold.

In contrast, the semiconductor device 1 of the first embodiment applies a threshold voltage to the first input terminal of a comparator and applies a triangular wave voltage to the second input terminal of that comparator. With respect to the triangular wave voltage, there are a period of time in which the voltage increases monotonically and a period of time in which the voltage decreases monotonically, and the magnitude of the voltage is determined with reference to an arbitrary point of time. Therefore, the comparator compares voltages of various different magnitudes with a voltage that can be regarded as being actually compared in the comparator, and produces an output signal indicating the result of the comparison.

For example, the semiconductor device 1 determines whether the timing at which the output signal switches between the H level and the L level is within an OK range that includes a timing at which the triangular wave voltage applied to the second input terminal of the comparator becomes equal to the threshold voltage. If the above timing is not within the OK range, the voltage which can be regarded as being actually compared in the comparator differs from the pre-designed threshold voltage more than an allowable range, and the semiconductor device 1 can therefore determine that a threshold failure due to, for example, a leak current or an open circuit is occurring. As described above, the semiconductor device 1 can perform a threshold failure determination for the comparator, based on whether or not the threshold voltage is within a certain range. Also, the semiconductor device 1 can notify the control unit 3, to which the semiconductor device 1 is connected, of the detected threshold failure, and/or notify an external apparatus through a communication device.

Furthermore, the semiconductor device 1 of the first embodiment has the following advantages.

In general, a comparator is used as a function monitoring circuit that performs systematic abnormality detection or detects an operation mode switching etc. of the system SYS, as in the function monitoring mode described above. As long as the system SYS is in normal operation, the comparator usually performs this kind of operation, so that it is not possible to diagnose the failure of the comparator. Therefore, the failure diagnosis of the comparator is usually performed only once every time the system SYS is activated, that is, at a time before system activation at which the entire system SYS is reset.

It should be noted that the semiconductor device 1 includes AND circuits AND_1, . . . , AND_n provided on the signal transmission path to the control unit 3. For example, where there is a timing at which the function monitoring by the comparator is unnecessary during a normal operation of the system SYS including the semiconductor device 1, a control signal supplied to one input terminal of an AND circuit is controlled to be at the L level. Owing to this, even when the semiconductor device 1 performs a failure diagnosis of the comparator, an output signal from the comparator indicating abnormality notification or the like is not transmitted to the control unit 3. Therefore, during the normal operation of the system SYS, the semiconductor device 1 can execute the failure diagnosis of the comparator without increasing the load of the control unit 3. As described above, the semiconductor device 1 can execute the failure diagnosis of the comparator even during the system operation, and the failure diagnosis of the comparator does not increase the load of the control unit 3 and can therefore be repeatedly executed. In this manner, the semiconductor device 1 can increase the frequency of failure diagnosis of the comparator, and therefore reliability of the comparator can be kept, for example, even during the normal operation of the system SYS.

Further, the semiconductor device 1 includes one or more detection units 10_1, . . . , 10_n each including a comparator connected to a node to which a triangular wave voltage is applied via a switch, and also includes a pass/fail determination circuit 302 to which the detection units 10_1, . . . , 10_n are connected and which diagnoses the threshold failure. Therefore, the semiconductor device 1 can diagnose the threshold failure of an arbitrary comparator by turning on only the switch connected to the detection unit including the comparator for which the threshold failure diagnosis is to be performed. By sequentially controlling the switches, the threshold failures of the respective comparators can be sequentially diagnosed.

### Second Embodiment

A semiconductor device 1 according to the second embodiment will be described in detail below. The semiconductor device 1 of the second embodiment corresponds to the semiconductor device prepared by changing the semiconductor device 1 of the first embodiment shown in FIG. 2 so that the failure diagnosis unit 30 includes pass/fail determination circuits 302_1, . . . , 302_n and data registers 303_1, . . . , 303_n instead of the pass/fail determination circuit 302 and the data register 303. In the description set forth below, descriptions of the same points as to the first embodiment will be omitted, and those of different points will be mainly explained.

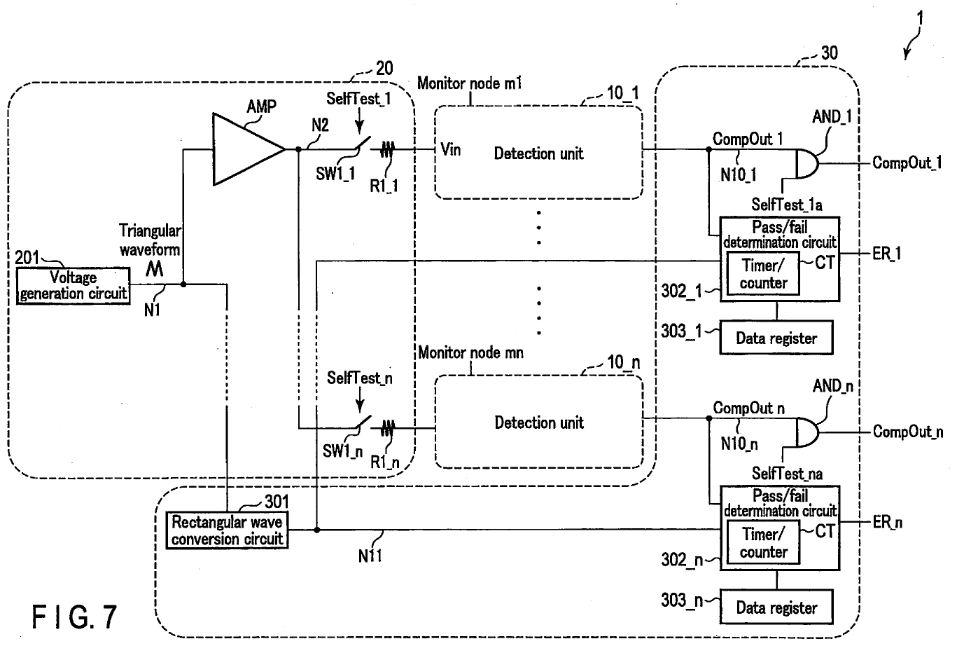

FIG. 7 is a diagram showing an example of a circuit configuration of the semiconductor device 1 according to the second embodiment.

In the semiconductor device 1 of the second embodiment, the comparison voltage generation unit 20 does not have to include illustrated switches SW1_1, . . . , SW1_n.

In the semiconductor device 1 of the second embodiment, the node to which the output terminal of comparator CMP_1 of detection unit 10_1 is connected is referred to as node N10_1. In the semiconductor device 1 of the second embodiment as well, for example, the output terminals of detection units 10_1, . . . , 10_n are connected to different nodes.

Next, a configuration of the failure diagnosis unit 30 will be described.

The output terminal of the rectangular wave conversion circuit 301 is connected to node N11.

The first input terminals of pass/fail determination circuits 302_1, . . . , 302_n are connected to node N11. Pass/fail determination circuits 3021, . . . , 302_n are associated in one to one correspondence with respective detection units 10_1, . . . , 10_n. The second input terminals of pass/fail determination circuits 3021, . . . , 302_n are connected to the output terminals of the comparators of the associated ones of detection units 10_1, . . . , 10_n. For example, the second input terminal of pass/fail determination circuit 302_1 is connected to node N10_1 to which the output terminal of comparator CMP_1 of detection unit 10_1 is connected. Pass/fail determination circuits 3021, . . . , 302_n are associated in one to one correspondence with respective data registers 303_1, . . . , 303_n. The first output terminals of pass/fail determination circuits 302_1, . . . , 302_n are connected to associated ones of data registers 303_1, . . . , 303_n. For example, the first output terminal of pass/fail determination circuit 302_1 is connected to data register 303_1. Each of pass/fail determination circuits 302_1, . . . , 302_n includes a timer/counter CT.

The first input terminals of the AND circuits AND_1, . . . , AND_n are connected to associated ones of the detection units 10_1, . . . , 10_n. For example, the first input terminal of the AND circuit AND_1 is connected to node N10_1.

The rectangular wave conversion circuit 301 supplies the converted rectangular wave signal to the pass/fail determination circuits 302_1, . . . , 302_n. The rectangular wave signal is supplied to the timer/counter CT of each of the pass/fail determination circuits 302_1, . . . , 302_n.

The timer/counter CT of each of the pass/fail determination circuits 302_1, . . . , 302_n generates a clock signal, counts the periods of the clock signal, and holds the count result as a timer/counter value, in the same manner as described above in connection with pass/fail determination circuit 302 of the first embodiment. Each of the pass/fail determination circuits 302_1, . . . , 302_n receives an output signal from the comparator of the associated detection unit. For example, pass/fail determination circuit 302_1 receives output signal CompOut1 from comparator CMP_1 of detection unit 10_1. Each of pass/fail determination circuits 302_1, . . . , 302_n determines whether or not the comparator of the associated detection unit works properly, using the timer/counter value and the output signal from the comparator of the associated detection unit, in the same manner as described above in connection with pass/fail determination circuit 302 of the first embodiment. In each of the pass/fail determination circuits, the above-described first OK range and second OK range are set for the associated detection unit, for example.

In addition, each of the pass/fail determination circuits 302_1, . . . , 302_n transfers the latched timer/counter value to the associated one of the data registers 303_1, . . . , and 303_n, and each of the data registers 303_1, . . . , 303_n fetches the transferred timer/counter value in the same manner as described above in connection with the data register 303 of the first embodiment.

Like the semiconductor device 1 of the first embodiment, the semiconductor device 1 of the second embodiment applies a threshold voltage to the first input terminal of a comparator and applies a triangular wave voltage to the second input terminal of that comparator. Therefore, the semiconductor device 1 of the second embodiment can perform threshold failure determination for the comparator in the same manner as described in connection with the first embodiment.

Further, similarly to the semiconductor device 1 of the first embodiment, the semiconductor device 1 of the second embodiment includes AND circuits AND_1, . . . , AND_n provided on the signal transmission path to the control unit 3. Therefore, the semiconductor device 1 of the second embodiment can repeatedly execute the failure diagnosis of a comparator even during the system operation, as described above in connection with the first embodiment, and can therefore increase the frequency of failure diagnosis of the comparator.

Furthermore, the semiconductor device 1 of the second embodiment includes one or more detection units 10_1, . . . , 10_n each including a comparator and connected to a node to which a triangular wave voltage is applied, and also includes pass/fail determination circuits 302_1, . . . , 302_n which are connected to associated ones of the detection units 10_1, . . . , 10_n and which diagnose the threshold failure. The triangular wave voltage can be simultaneously applied to all of the detection units 10_1, . . . , 10_n, and output signals from the comparators of the associated detection units are supplied to the pass/fail determination circuits 302_1, . . . , 302_n, respectively. Therefore, the pass/fail determination circuits 302_1, . . . , 302_n can independently and simultaneously execute the diagnosis of the threshold failures of the comparators of the associated detection units.

### Third Embodiment

A semiconductor device 1 according to the third embodiment will be described in detail below. The semiconductor device 1 of the third embodiment corresponds to the semiconductor device prepared by changing the semiconductor device 1 of the first embodiment shown in FIG. 2 so that comparison voltage generation unit 20 uses a CR charging wave voltage instead of the triangular wave voltage. In the description set forth below, descriptions of the same points as to the first embodiment will be omitted, and those of different points will be mainly explained.

<3-1> Configuration

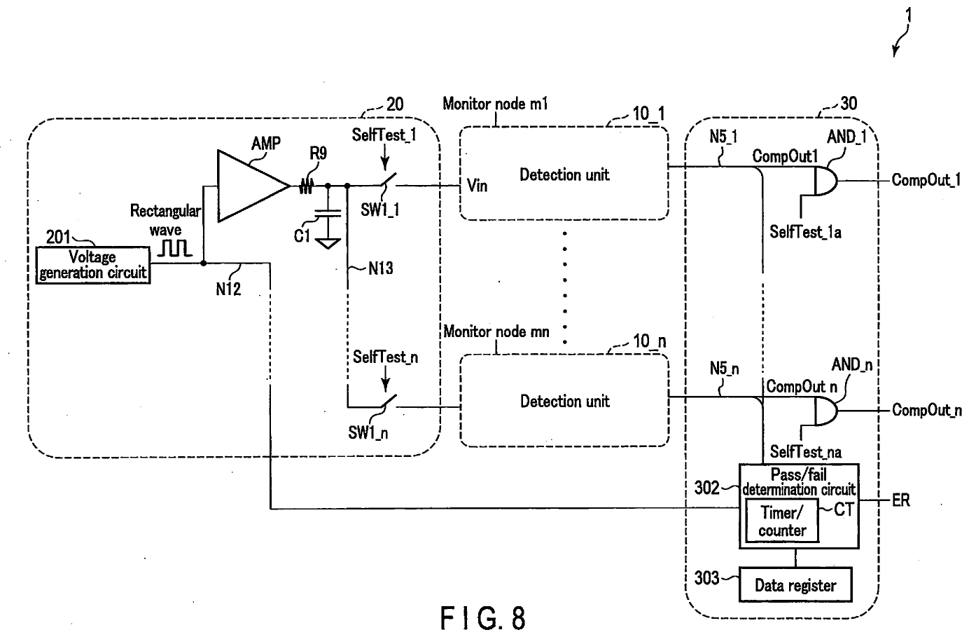

FIG. 8 is a diagram showing an example of a circuit configuration of the semiconductor device 1 according to the third embodiment.

First, the configuration of the comparison voltage generation unit 20 will be described.

The comparison voltage generation unit 20 includes a voltage generation circuit 201, a buffer amplifier AMP, a resistor element R9, a capacitor C1, and switches SW1_1, . . . , SW1_n.

The voltage generation circuit 201 generates a rectangular wave signal and outputs the generated rectangular wave signal on the output terminal. The output terminal of the voltage generation circuit 201 is connected to node N12.

The input terminal of the buffer amplifier AMP is connected to node N12. The buffer amplifier AMP receives the rectangular wave signal via node N12, amplifies the received rectangular wave signal, and outputs the amplified rectangular wave signal on the output terminal.

The first terminal of resistor element R9 is connected to the output terminal of the buffer amplifier AMP, and the second terminal of resistor element R9 is connected to node N13. The first terminal of the capacitor C1 is connected to node N13, and the second terminal of the capacitor C1 is grounded. A CR charging wave voltage is generated from the rectangular wave signal output from the voltage generation circuit 201 by means of the buffer amplifier AMP, the resistor element R9, and the capacitor C1, and the CR charging wave voltage is applied to node N13. For example, the CR charging wave voltage monotonically increases when the rectangular wave signal output from the voltage generation circuit 201 is at the H level, and monotonically decreases when the rectangular wave signal is at the L level. Hereinafter, a description will be given of the case where the CR charging wave voltage changes as above. With respect to the CR charging waveform, however, the condition of the rectangular wave signal under which the CR charging voltage monotonically increases and the condition of the rectangular wave signal under which the voltage monotonically decreases may be different from those described above.

The first terminals of switches SW1_1, . . . , SW1_n are connected to node N13. The second terminals of switches SW1_1, . . . , SW1_n are connected to the associated ones of the detection units 10_1, . . . , 10_n. For example, the second terminal of switch SW1_1 is connected to node N3 to which the non-inverting input terminal of comparator CMP_1 of detection unit 10_1 is connected.

Similarly to the first embodiment, each of switches SW1_1, . . . , SW1_n functions as a switch for selecting whether or not to supply a CR charging wave voltage to the associated detection unit. For example, when switch SW1_1 is in the ON state, the CR charging wave voltage applied to node N13 is applied to node N3. When switch SW1_1 is in the OFF state, node N13 and node N3 are disconnected from each other, so that the CR charging wave voltage is not applied to node N3.

As described above in connection with the first embodiment, by turning on and off switches SW1_1, . . . , SW1_n, the detection units associated with those switches switch between the function monitoring mode and the comparator diagnosis mode.

Next, a configuration of the failure diagnosis unit 30 will be described. By the failure diagnosis unit 30, diagnosis of the above-described threshold failure can be executed for the comparator included in a detection unit that is in the comparator diagnosis mode.

The failure diagnosis unit 30 includes a pass/fail determination circuit 302, a data register 303, and AND circuits AND_1, . . . , AND_n.

The connection relation among the pass/fail determination circuit 302, the data register 303 and the AND circuits AND_1, . . . , AND_n is similar to that described in connection with the first embodiment, except that the first input terminal of the pass/fail determination circuit 302 is connected to node N12.

The pass/fail determination circuit 302 is supplied with a rectangular wave signal generated by the voltage generation circuit 201 via node N12. The pass/fail determination circuit 302 uses this rectangular wave signal in place of the rectangular wave signal supplied from the rectangular wave conversion circuit 301 used in the first embodiment, and performs the same processing as described in connection with the first embodiment.

<3-2> Operation

Next, a description will be given of an operation of the semiconductor device 1 of the third embodiment.

With respect to an operation performed in the comparator diagnosis mode, the manner in which detection unit 10_1 operates in the comparator diagnosis mode will be described by way of example in the description below, but the other detection units operate in the same manner.

In the comparator diagnosis mode, switch SW1_1 is in the ON state, as described above. Therefore, voltage Vin, which is determined by resistor elements R2_1 and R3_1 and a CR charging wave voltage applied to node N13 by means of buffer amplifier AMP, resistor element R9 and capacitor C1, is applied to the non-inverting input terminal of comparator CMP_1.

The timer/counter CT starts time measurement based on the timer/counter value, for example, with the time at which the rectangular wave signal supplied from the voltage generation circuit 201 rises from the L level to the H level as a first measurement start time. Thereafter, the timer/counter CT latches the timer/counter value obtained at the time when voltage Vin gradually rises and output signal CompOut1 rises from the L level to the H level. The timer/counter CT starts time measurement based on the timer/counter value, for example, with the time at which the rectangular wave signal supplied from the voltage generation circuit 201 falls from the H level to the L level as a second measurement start time. Thereafter, the timer/counter CT latches the timer/counter value obtained at the time when voltage Vin gradually falls and output signal CompOut1 falls from the H level to the L level.

Next, the pass/fail determination circuit 302 executes the pass/fail determination based on the latched timer/counter values, in the same manner as described in connection with the first embodiment.

The above operation will be described in order of time with reference to timing charts.

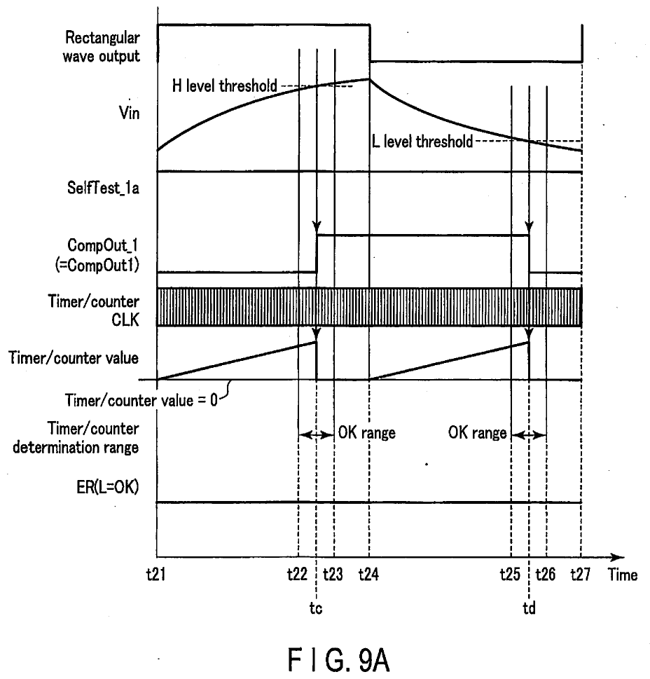

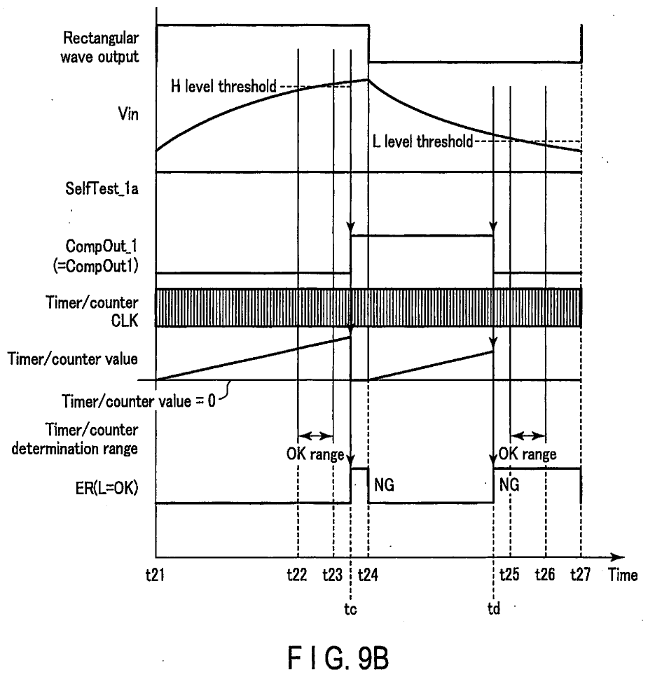

FIGS. 9A and 9B are timing charts showing an example of how various signals used in the operation of the semiconductor device 1 of the third embodiment vary with time. Note that the timing charts shown in FIGS. 9A and 9B are an example of the timing charts of the case where switch SW1_1 is turned on and a threshold failure of comparator CMP_1 is diagnosed based on output signal CompOut1 supplied from comparator CMP_1 of detection unit 10_1. By causing AND circuit AND_1 associated with detection unit 10_1 to receive control signal SelfTest_1a at the H level, output signal CompOut_1 is output from the output terminal of AND circuit AND_1 at the same logic level as output signal CompOut1 and is supplied, for example, to the control unit 3.

The rectangular wave signal supplied from the voltage generation circuit 201 to the pass/fail determination circuit 302 rises from the L level to the H level at time t21, and maintains the H level until time t24. Voltage Vin applied to the non-inverting input terminal of comparator CMP_1 has a CR charging waveform, and voltage Vin increases monotonically from time t21 to time t24.

In the pass/fail determination circuit 302, the timer/counter CT starts time measurement based on the timer/counter value, with time t21 as a first measurement start time. During the period from time t21 to time t24, voltage Vin gradually rises, and output signal CompOut1 supplied from comparator CMP_1 and input to pass/fail determination circuit 302 rises from the L level to the H level at time tc. The timer/counter CT latches the timer/counter value obtained at time tc.

The pass/fail determination circuit 302 executes the pass/fail determination based on the timer/counter value latched on the basis of time t21. Specifically, the pass/fail determination circuit 302 determines whether or not the timer/counter value latched on the basis of time t21 is within a first OK range. The first OK range corresponds to an allowable time period from time t22 to time t23, in which it can be determined that, for example, comparator CMP_1 does not undergo a threshold failure, and which includes a timing at which gradually increasing voltage Vin becomes equal to the H level threshold voltage. The time period from time t21 to time t22 and the time period from time t21 to time t23 are preset in the pass/fail determination circuit 302. That is, the values that the timer/counter value should be at times t22 and t23 when counting is started at time t21 are stored in the pass/fail determination circuit 302 in advance. Then, the pass/fail determination circuit 302 determines whether or not the timer/counter value latched at time tc is within the interval between the timer/counter values corresponding to times t22 and t23.

In the example shown in FIG. 9A, the timer/counter value latched on the basis of time t21 is within the first OK range. Therefore, in response to the determination that the timer/counter value latched on the basis of the time t21 is within the first OK range, the pass/fail determination circuit 302 outputs signal ER at the L level from the second output terminal of the pass/fail determination circuit 302.

The rectangular wave signal falls from the H level to the L level at time t24 and maintains the L level until time t27. Voltage Vin decreases monotonically from time t24 to time t27.

In the pass/fail determination circuit 302, the timer/counter CT starts time measurement based on the timer/counter value, with time t24 as a second measurement start time. During the period from time t24 to time t27, voltage Vin gradually falls, and output signal CompOut1 mentioned above falls from the H level to the L level at time td. The timer/counter CT latches the timer/counter value obtained at time td.

The pass/fail determination circuit 302 executes the pass/fail determination based on the timer/counter value latched on the basis of time t24. Specifically, the pass/fail determination circuit 302 determines whether or not the timer/counter value latched on the basis of time t24 is within a second OK range. The second OK range corresponds to an allowable time period from time t25 to time t26, in which it can be determined that, for example, comparator CMP_1 does not undergo a threshold failure, and which includes a timing at which gradually decreasing voltage Vin becomes equal to the L level threshold voltage. The time period from time t24 to time t25 and the time period from time t24 to time t26 are preset in the pass/fail determination circuit 302. That is, the values that the timer/counter value should be at times t25 and t26 when counting is started at time t24 are stored in the pass/fail determination circuit 302 in advance. Then, the pass/fail determination circuit 302 determines whether or not the timer/counter value latched at time td is within the interval between the timer/counter values corresponding to times t25 and t26.

In the example shown in FIG. 9A, the timer/counter value latched on the basis of time t24 is within the second OK range. Therefore, in response to the determination that the timer/counter value latched on the basis of the time t24 is within the second OK range, the pass/fail determination circuit 302 outputs signal ER at the L level from the second output terminal of the pass/fail determination circuit 302.

In the example shown in FIG. 9B, the timer/counter value latched on the basis of time t21 is not within the first OK range. Therefore, in response to the determination that the timer/counter value latched on the basis of the time t21 is not within the first OK range, the pass/fail determination circuit 302 outputs signal ER at the H level from the second output terminal of the pass/fail determination circuit 302 and keeps outputting that signal until time t24 at which the rectangular wave signal falls from the H level to the L level.

In the example shown in FIG. 9B, the timer/counter value latched on the basis of time t24 is not within the second OK range. Therefore, in response to the determination that the timer/counter value latched on the basis of the time t24 is not within the second OK range, the pass/fail determination circuit 302 outputs signal ER at the H level from the second output terminal of the pass/fail determination circuit 302 and keeps outputting that signal until time t27 at which the rectangular wave signal rises from the L level to the H level.

<3-3> Advantages

The semiconductor device 1 of the third embodiment applies a threshold voltage to the first input terminal of a comparator and applies a CR charging wave voltage to the second input terminal of that comparator. With respect to the CR charging wave voltage as well as the triangular wave voltage used in the first embodiment, there are a period of time in which the voltage monotonically increases and a period of time in which the voltage monotonically decreases, and the magnitude of the voltage is determined with reference to an arbitrary point of time. Therefore, the comparator compares voltages of various different magnitudes with a voltage that can be regarded as being actually compared in the comparator, and produces an output signal indicating the result of the comparison.

For example, the semiconductor device 1 of the third embodiment determines whether the timing at which the output signal switches between the H level and the L level is within an OK range that includes a timing at which the CR charging wave voltage applied to the second input terminal of the comparator becomes equal to the threshold voltage. If the above timing is not within the OK range, the voltage which can be regarded as being actually compared in the comparator differs from the pre-designed threshold voltage more than an allowable range, and therefore, the semiconductor device 1 of the third embodiment can determine that a threshold failure is occurring. As described above, like the semiconductor device 1 of the first embodiment, the semiconductor device 1 of the third embodiment can perform threshold failure determination for a comparator, based on whether or not the threshold voltage is within a certain range.

Further, similarly to the semiconductor device 1 of the first embodiment, the semiconductor device 1 of the third embodiment includes AND circuits AND_1, . . . , AND_n provided on the signal transmission path to the control unit 3. Therefore, the semiconductor device 1 of the third embodiment can repeatedly execute the failure diagnosis of the comparator even during the system operation, as described above in connection with the first embodiment, and can therefore increase the frequency of failure diagnosis of the comparator.

Further, the semiconductor device 1 of the third embodiment includes one or more detection units 10_1, . . . , 10_n each including a comparator and connected to a node to which a CR charging wave voltage is applied via a switch, and also includes a pass/fail determination circuit 302 to which the detection units 10_1, . . . , 10_n are connected and which diagnoses the threshold failure. Therefore, in the same manner as described in connection with the first embodiment, the semiconductor device 1 of the third embodiment can diagnose the threshold failure of an arbitrary comparator by turning on only the switch connected to the detection unit including the comparator for which the threshold failure diagnosis is to be performed. In the same manner as described in connection with the first embodiment, by sequentially controlling the switches, the threshold failures of the respective comparators can be sequentially diagnosed.

### Fourth Embodiment

A semiconductor device 1 according to the fourth embodiment will be described in detail below. The semiconductor device 1 of the fourth embodiment corresponds to the semiconductor device prepared by changing the semiconductor device 1 of the third embodiment shown in FIG. B so that the failure diagnosis unit 30 includes pass/fail determination circuits 302_1, . . . , 302_n and data registers 303_1, . . . , 303_n instead of the pass/fail determination circuit 302 and the data register 303. In the description set forth below, descriptions of the same points to the third embodiment will be omitted, and those of different points will be mainly explained.

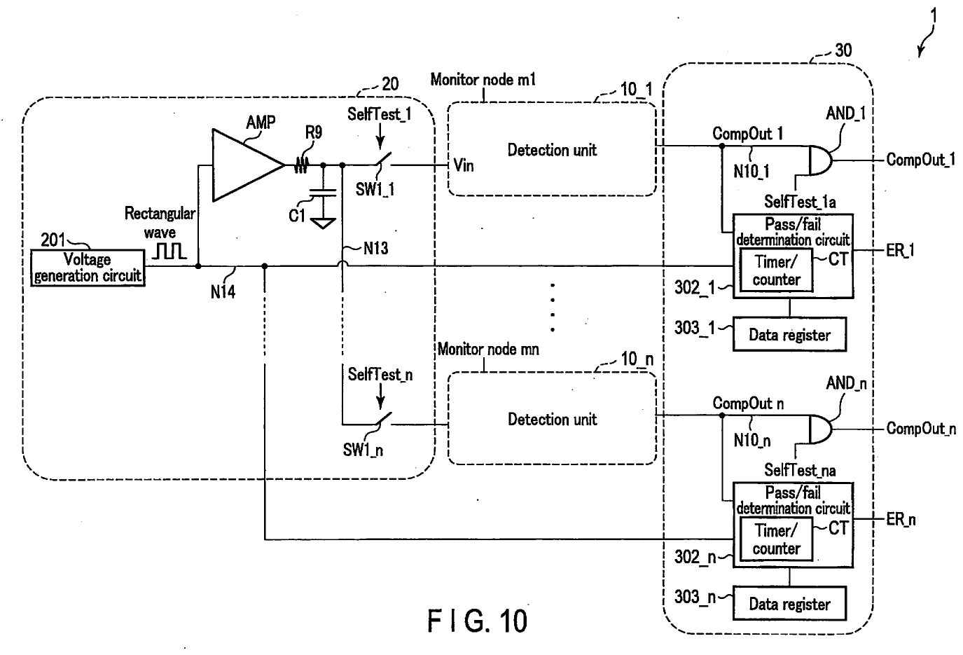

FIG. 10 is a diagram showing an example of a circuit configuration of the semiconductor device 1 according to the fourth embodiment.

The node to which the output terminal of the voltage generation circuit 201 and the input terminal of the buffer amplifier AMP are connected is node N14. In the semiconductor device 1 of the fourth embodiment, the comparison voltage generation unit 20 does not have to include illustrated switches SW1_1, . . . , SW1_n.

In the semiconductor device 1 of the fourth embodiment, the node to which the output terminal of comparator CMP_1 of detection unit 10_1 is connected is referred to as node N10_1, as in the second embodiment. In the semiconductor device 1 of the fourth embodiment as well, for example, the output terminals of detection units 10_1, . . . , 10_n are connected to different nodes.

Next, a configuration of the failure diagnosis unit 30 will be described.

The connection relation among the pass/fail determination circuits 302_1, . . . , 302_n, the data registers 303_1, . . . , 303_n and the AND circuits AND_1, . . . , AND_n is similar to that described in connection with the second embodiment, except that the first input terminals of the pass/fail determination circuits 302_1, . . . , 302_n are connected to node N14.

The pass/fail determination circuits 302_1, . . . , 302_n are supplied with a rectangular wave signal generated by the voltage generation circuit 201 via node N14.

Each of the data registers 303_1, . . . , 303_n performs the same processing as described in connection with the data register 303 of the first embodiment.

Like the semiconductor device 1 of the third embodiment, the semiconductor device 1 of the fourth embodiment applies a threshold voltage to the first input terminal of a comparator and applies a CR charging wave voltage to the second input terminal of that comparator. Therefore, the semiconductor device 1 of the fourth embodiment can perform threshold failure determination for the comparator in the same manner as described in connection with the first embodiment.

Further, similarly to the semiconductor device 1 of the first embodiment, the semiconductor device 1 of the fourth embodiment includes AND circuits AND_1, . . . , AND_n provided on the signal transmission path to the control unit 3. Therefore, the semiconductor device 1 of the fourth embodiment can repeatedly execute the failure diagnosis of the comparator even during the system operation, as described above in connection with the first embodiment, and can therefore increase the frequency of failure diagnosis of the comparator.

Furthermore, the semiconductor device 1 of the fourth embodiment includes one or more detection units 10_1, . . . , 10_n each including a comparator and connected to a node to which the CR charging wave voltage is applied, and also includes pass/fail determination circuits 3021, . . . , 302_n which are connected to associated ones of the detection units 10_1, . . . , 10_n and which diagnose the threshold failure. The CR charging wave voltage can be simultaneously applied to all of the detection units 10_1, . . . , 10_n, and output signals from the comparators of the associated detection units are supplied to the pass/fail determination circuits 302_1, . . . , 302_n, respectively. Therefore, the pass/fail determination circuits 302_1, . . . , 302_n can independently and simultaneously execute the diagnosis of the threshold failures of the comparators of the associated detection units.

### Fifth Embodiment

A semiconductor device 1 according to the fifth embodiment will be described in detail below.

<5-1> Configuration

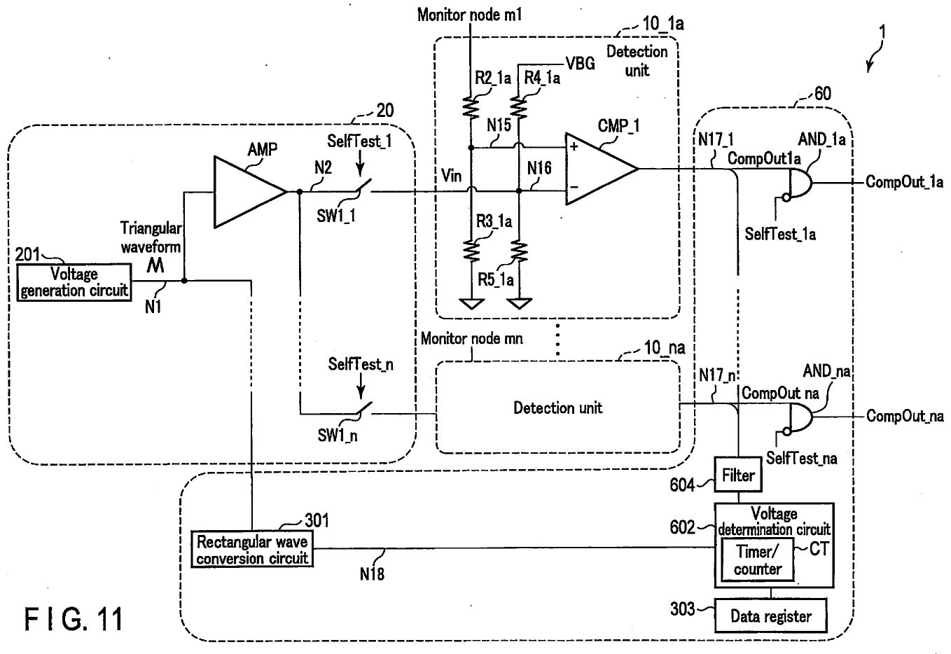

FIG. 11 is a diagram showing an example of a circuit configuration of the semiconductor device 1 according to the fifth embodiment.

The semiconductor device 1 of the fifth embodiment includes one or more detection units 10_1a, . . . , 10_na each including a comparator, a comparison voltage generation unit 20, and a voltage determination unit 60. The semiconductor device 1 of the fifth embodiment is capable of determining the magnitude of the voltage on which the functions to be monitored by using the detection units 10_1a, . . . , 10_na are operating.

First, the configuration of the comparison voltage generation unit 20 will be described.

The comparison voltage generation unit 20 includes a voltage generation circuit 201, a buffer amplifier AMP, and switches SW1_1, . . . , SW1_n.

Switches SW1_1, . . . , SW1_n are associated in one to one correspondence with detection units 10_1a, . . . , 10_na, respectively. The second terminals of switches SW1_1, . . . , SW1_n are connected to the associated ones of the detection units 10_1a . . . , 10_na. For example, the second terminal of switch SW1_1 is connected to node N16 to which the inverting input terminal of comparator CMP_1 of detection unit 10_1a is connected. The connection relation among the voltage generation circuit 201, the buffer amplifier AMP, and the switches SW1_1, . . . , and SW1_n is similar to that described in connection with the first embodiment, except for the connection destinations of the second terminals of switches SW1_1, . . . , SW1_n.

For example, when switch SW1_1 is in the ON state, the triangular wave voltage applied to node N2 by buffer amplifier AMP is applied to node N16.

Next, configurations of detection units 10_1a, . . . , 10_na will be described.

In the description set forth below, detection unit 10_1a will be mentioned as an example, but the other detection units have the same configuration as detection unit 10_1a.

Detection unit 10_1a includes comparator CMP_1 and resistor elements R2_1a, R3_1a, R4_1a and R5_1a.

The first terminal of resistor element R2_1a is connected to monitor node m1, and the second terminal of resistor element R2_1a is connected to node N15. The monitor node m1 is connected to the function that is to be monitored in the driver circuit 2.

The first terminal of resistor element R3_1a is connected to node N15, and the second terminal of resistor element R3_1a is grounded.

The first terminal of resistor element R4_1a is connected to a voltage source VBG, and the second terminal of resistor element R4_1a is connected to node N16.

The first terminal of resistor element R5_1a is connected to node N16, and the second terminal of resistor element R5_1a is grounded.

The non-inverting input terminal of comparator CMP_1 is connected to node N15, the inverting input terminal of comparator CMP_1 is connected to node N16, and the output terminal of comparator CMP_1 is connected to node N17_1. For example, the output terminals of detection units 10_1a, . . . , 10_na are connected to different nodes.

Comparator CMP_1 compares the voltage applied to the non-inverting input terminal with the voltage applied to the inverting input terminal, and outputs an output signal CompOut1a indicating the result of the comparison from the output terminal of comparator CMP_1. For example, if the output signal CompOut1a is at the L level, this indicates that the voltage applied to the non-inverting input terminal is lower than the voltage applied to the inverting input terminal. On the other hand, for example, if the output signal CompOut1a is at the H level, this indicates that the voltage applied to the non-inverting input terminal is higher than the voltage applied to the inverting input terminal.

Finally, a configuration of the voltage determination unit 60 will be described. With respect to the function to be monitored by using the detection unit whose associated switch is in the ON state, the voltage determination unit 60 can execute the above-described voltage determination.

The voltage determination unit 60 includes a rectangular wave conversion circuit 301, a voltage determination circuit 602, a data register 303, a filter 604, and AND circuits AND_1a, . . . , AND_na.

The input terminal of the rectangular wave conversion circuit 301 is connected to node N1 to which the output terminal of the voltage generation circuit 201 is connected, and the output terminal of the rectangular wave conversion circuit 301 is connected to node N18.

The input terminal of the filter 604 is connected to an n-bit signal line that can reflect output signals from the detection units. In the n-bit signal line, the wiring of each one bit reflects an output signal from the comparator included in one of the detection units 10_1a, . . . , 10_na. The output terminal of the filter 604 is connected to the first input terminal of the voltage determination circuit 602.

The second input terminal of the voltage determination circuit 602 is connected to node N18. The first output terminal of the voltage determination circuit 602 is connected to the data register 303. The voltage determination circuit 602 includes a timer/counter CT.

Each of AND circuits AND_1a, . . . , AND_na is associated in one to one correspondence with one of detection units 10_1a, . . . , 10_na. The first input terminals of AND circuits AND_1a, . . . , AND_na are connected to associated ones of the detection units 10_1a, . . . , 10_na. For example, the first input terminal of AND circuit AND_1a is connected to node N17_1 to which the output terminal of comparator CMP_1 of detection unit 10_1a is connected. Control signals SelfTest_1a, . . . , SelfTest_na are inverted and supplied to the second input terminals of AND circuits AND_1a, . . . , AND_na, respectively. For example, control signals SelfTest_1a, . . . , SelfTest_na may be signals that can be responsive to the corresponding ones of control signals SelfTest_1, . . . , SelfTest_n. The output terminals of AND circuits AND_1a, . . . , AND_na are connected to the control unit 3, for example.

A triangular wave voltage generated by the voltage generation circuit 201 is supplied via node N1 to the rectangular wave conversion circuit 301. The rectangular wave conversion circuit 301 converts the supplied triangular wave voltage into a rectangular wave signal and supplies the converted rectangular wave signal to the voltage determination circuit 602. For example, the rectangular wave signal falls from the H level to the L level at the time when the triangular wave voltage becomes minimum, and rises from the L level to the H level at the time when the triangular wave voltage becomes maximum. Hereinafter, the case where the rectangular wave signal behaves in the above manner will be described by way of example, but the condition of the triangular waveform under which the rectangular wave signal rises and the condition of the triangular waveform under which the rectangular wave signal falls may be different from those described above. The rectangular wave signal is supplied to the timer/counter CT of the voltage determination circuit 602.

The timer/counter CT of the voltage determination circuit 602 generates a clock signal, counts the periods of the clock signal, and holds the count result as a timer/counter value. Also, the voltage determination circuit 602 receives output signals CompOut1a, . . . , CompOutna from the comparators of the detection units 10_1a, . . . , 10_na via the filter 604. The voltage determination circuit 602 determines the magnitudes of voltages on which the functions to be monitored by using the detection units 10_1a, . . . , 10_na are operating, using the timer/counter values and the output signals CompOut1a, CompOutna.

Further, the voltage determination circuit 602 transfers, for example, data indicating the determined magnitude of the voltage to the data register 303, and the data register 303 fetches the transferred data.

<5-2> Operation

Next, a description will be given of an operation of the semiconductor device 1 of the fifth embodiment.

In the description set forth below, reference will be made to the case where the magnitude of the voltage on which the function to be monitored by using detection unit 10_1a is operating is determined, but the same explanation holds true of the cases of the other detection units.

In this case, switch SW1_1 is in the ON state, as described above. Therefore, voltage Vin, which is determined by resistor elements R4_1a and R5_1a and a triangular wave voltage applied to node N2 by buffer amplifier AMP, is applied to the inverting input terminal of comparator CMP_1. On the other hand, the non-inverting input terminal of comparator CMP_1 is applied with a voltage obtained by dividing a voltage which is applied to monitor node m1 and on which the function to be monitored is operating by the resistance of resistor element R2_1a and the resistance of resistor element R3_1a.

The timer/counter CT starts time measurement based on the timer/counter value, for example, with the time at which the rectangular wave signal supplied from the rectangular wave conversion circuit 301 falls from the H level to the L level as a first measurement start time. Thereafter, the timer/counter CT latches the timer/counter value obtained at the time when voltage Vin gradually rises and output signal CompOut1a falls from the H level to the L level. Further, the timer/counter CT starts time measurement based on the timer/counter value, for example, with the time at which the rectangular wave signal rises from the L level to the H level as a second measurement start time. Thereafter, the timer/counter CT latches the timer/counter value obtained at the time when voltage Vin gradually lowers and output signal CompOut1a rises from the L level to the H level.

Next, the voltage determination circuit 602 executes the voltage determination based on the latched timer/counter values. Specifically, based on the timer/counter value latched on the basis of the first measurement start time or the second measurement start time, the voltage determination circuit 602 determines the magnitude of the voltage on which the function to be monitored by using the detection unit 10_1a is operating.

As described above, the data indicating the determined magnitude of the voltage is fetched into the data register 303. Therefore, the voltage on which the function to be monitored by using the detection unit 10_1a is operating can be monitored by use of a communication device (not shown), and a determination can be made by a device external to the semiconductor device 1.

In addition, when the magnitude of the voltage on which the function to be monitored by using detection unit 10_1a is operating is determined, it is possible to control whether or not to notify the control unit 3. For example, where control signal SelfTest_1a is at the L level, output signal CompOut_1a is output from the output terminal of AND circuit AND_1a such that it has the same logic level as output signal CompOut1a from comparator CMP_1. On the other hand, where control signal SelfTest_1a is at the H level, output signal CompOut_1a is output at the L level from the output terminal of AND circuit AND_1a.

The above operation will be described in order of time with reference to timing charts.

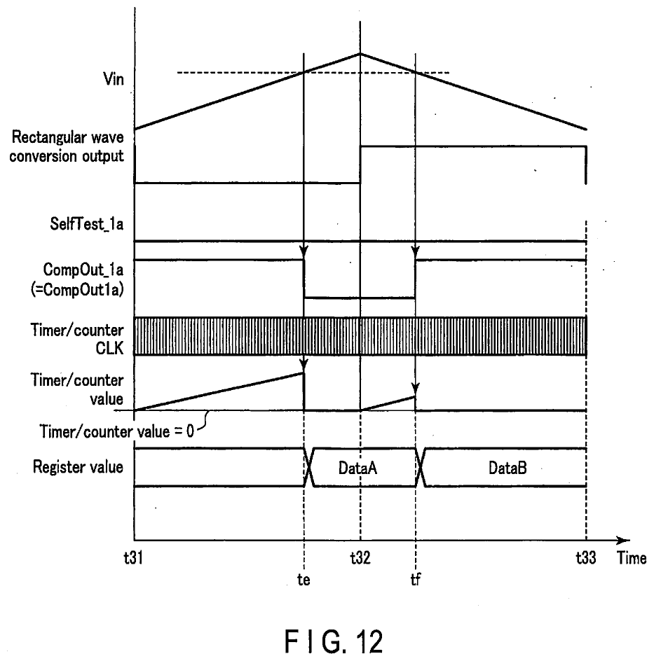

FIG. 12 is a timing chart showing an example of how various signals used in the operation of the semiconductor device 1 of the fifth embodiment vary with time. The timing chart shown in FIG. 12 is an example of the timing chart of the case where switch SW1_1 is turned on and the magnitude of the voltage on which the function to be monitored by using detection unit 10_1a is operating is determined based on output signal CompOut1a supplied from comparator CMP_1 of detection unit 10_1a. By causing AND circuit AND_1a associated with detection unit 10_1a to receive control signal SelfTest_1a at the L level; output signal CompOut_1a is output from the output terminal of AND circuit AND_1a at the same logic level as output signal CompOut1a and is supplied, for example, to the control unit 3.

Voltage Vin applied to the inverting input terminal of comparator CMP_1 has a triangular waveform, and voltage Vin increases monotonically from time t31 to time t32. The rectangular wave signal supplied from the rectangular wave conversion circuit 301 to the voltage determination circuit 602 falls from the H level to the L level at time t31, and maintains the L level until time t32.

In the voltage determination circuit 602, the timer/counter CT starts time measurement based on the timer/counter value, with time t31 as a first measurement start time. During the period from time t31 to time t32, voltage Vin gradually rises, and output signal CompOut1a supplied from comparator CMP_1 and input to voltage determination circuit 602 falls from the H level to the L level at time te. The timer/counter CT latches the timer/counter value obtained at time te.

Based on the timer/counter value latched on the basis of time t31, the voltage determination circuit 602 determines the magnitude of the voltage on which the function to be monitored by using detection unit 10_1a is operating. For example, the voltage determination circuit 602 supplies data A indicating the determined magnitude of the voltage to the data register 303.

Voltage Vin decreases monotonically from time t32 to time t33. The rectangular wave signal rises from the L level to the H level at time t32 and maintains the H level until time t33.

In the voltage determination circuit 602, the timer/counter CT starts time measurement based on the timer/counter value, with time t32 as a second measurement start time. During the period from time t32 to time t33, voltage Vin gradually falls, and output signal CompOut1a mentioned above rises from the L level to the H level at time tf. The timer/counter CT latches the timer/counter value obtained at time tf.

Based on the timer/counter value latched on the basis of time t32, the voltage determination circuit 602 determines the magnitude of the voltage on which the function to be monitored by using detection unit 10_1a is operating. For example, the voltage determination circuit 602 supplies data B indicating the determined magnitude of the voltage to the data register 303.

<5-3> Advantages

The semiconductor device 1 of the fifth embodiment applies a triangular wave voltage to the first input terminal of a comparator and applies a voltage based on the voltage on which the function to be monitored is operating to the second input terminal of that comparator. With respect to the triangular wave voltage, there are a period of time in which the voltage monotonically increases and a period of time in which the voltage monotonically decreases, and the magnitude of the voltage is determined with reference to an arbitrary point of time. Therefore, the comparator compares voltages of various different magnitudes with the voltage on which the function to be monitored is operating, and produces an output signal indicating the result of the comparison. The semiconductor device 1 of the fifth embodiment can determine the magnitude of the voltage on which the function to be monitored is operating based on the timing at which the output signal switches between the H level and the L level. The semiconductor device 1 of the fifth embodiment can notify the control unit 3, to which the semiconductor device 1 is connected, of the determined magnitude of the voltage, and/or notify an external apparatus through a communication device. Therefore, for example, the semiconductor device 1 of the fifth embodiment can calculate a difference between the magnitude of the voltage that is set to enable the function to be monitored to operate and the magnitude of the voltage on which the function is actually operating, and causes this difference to be reflected in the operation of the entire system SYS.

### Other Embodiments

In connection with the semiconductor device of each of the above embodiments, reference was made to a specific example of the comparator included in the semiconductor device and voltages applied to the two input terminals of the comparator. However, the semiconductor device is not limited to the configurations detailed above. For example, the semiconductor device may be configured such that the voltage applied to the input terminal of the comparator is applied to an input terminal different from that described above. In such a case, various processes which the pass/fail determination circuit and the voltage determination circuit execute based on the logic levels of signals may be properly modified without departing from the gist of the invention. For example, the comparator can be configured freely as long as two kinds of voltages as detailed above are respectively applied to the input terminals and an output signal based on the comparison of the two kinds of voltages is output.

In connection with the first embodiment and the second embodiment, reference was made to an example in which the semiconductor device uses a triangular wave voltage, and in connection with the third embodiment and the fourth embodiment, reference was made to an example in which the semiconductor device uses a CR charging wave voltage. However, the semiconductor device may be configured to use a voltage that monotonically increases or decreases in an arbitrary period of time, instead of the triangular wave voltage and the CR charging wave voltage.

In connection with the fifth embodiment, reference was made to the configuration and operation of the semiconductor device that determines the magnitude of the voltage on which the function to be monitored operates by using a triangular wave voltage. However, as described above in connection with the third embodiment, the fourth embodiment and the like, the semiconductor device may be configured to determine the above-mentioned magnitude of the voltage by using the CR charging wave voltage or the like instead of the triangular wave voltage.

Furthermore, in connection with the fifth embodiment, reference was made to the semiconductor device in which one voltage determination circuit is connected to one or more detection units, and that voltage determination circuit determines the magnitude of the voltage on which a function to be monitored by using an arbitrary one of the one or more detection units is operating. However, as described above in connection with the second embodiment and the fourth embodiment, the semiconductor device may be configured such that detection units and voltage determination circuits are associated in one to one correspondence with each other and each voltage determination circuit performs the voltage determination with respect to the function to be monitored by using the associated detection unit.

In each of the above embodiments, applying or supplying a voltage may include applying or supplying a voltage of, for example, 0V. Outputting a signal at a level may include outputting a voltage of, for example, 0V.

In the above description of the embodiments, a monotonic increase or monotonic decrease of a voltage or a continuous increase or continuous decrease of a voltage is described. The monotonic increase or continuous increase of the voltage may include a case where the voltage is constant or decreases in a very short period of time. Similarly, the monotonic decrease or continuous decrease of the voltage may include a case where the voltage is constant or increases in a very short period of time.

For example, in the case of the monotonic increase or continuous increase of a voltage, the voltage may increase at every time interval of a time unit of a timer/counter, such as a cycle of a clock signal. Similarly, for example, in the case of the monotonic decrease or continuous decrease of a voltage, the voltage may decrease at every time interval mentioned above.

Alternatively, the voltage may increase or decrease at every time interval of a plurality of time units. The number of time units, which is the reference time interval, may be determined based on, for example, the number of time units that fall within a time period from the lower limit to the upper limit of the first OK range or the second OK range. For example, the more the number of time units that fall within the time period from the lower limit to the upper limit of the first OK range or the second OK range, the more the number of time units corresponding to the reference time interval can be.

In the present specification, the term “connection” means that elements are electrically connected, and does not exclude the case where another element is interposed therebetween. Also, the circuit configuration and/or operation of each of the above-described devices were merely presented as an example. For example, the circuit configuration of the semiconductor device and/or the detection unit can be variously modified and implemented without departing from the gist of the present invention.

While certain embodiments have been described, these embodiments have been presented by way of example only, and are not intended to limit the scope of the inventions. Indeed, the novel embodiments described herein may be embodied in, a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a comparator including a first input terminal and a second input terminal, and being configured to receive a first voltage at the first input terminal and to receive at the second input terminal a second voltage that continuously increases or decreases in a first period, the second voltage being equal in magnitude to the first voltage at a first timing in the first period; and
a first circuit configured to change a signal to be output, if a second timing at which an output signal from the comparator is switched is out of a second period including the first timing.

2. The device according to claim 1, wherein the first circuit is configured to change the signal to be output from a signal of a first level to a signal of a second level, which is different from the first level, if the second timing is out of the second period.

3. The device according to claim 2, wherein the signal of the second level has a voltage higher than that of the signal of the first level.

4. The device according to claim 1, wherein the first voltage is a constant voltage.

5. The device according to claim 1, wherein the first circuit measures the second timing based on a count of periods of a clock signal.

6. The device according to claim 1, wherein the second voltage has a triangular waveform or a CR charging waveform.

7. The device according to claim 1, wherein
the second input terminal is selectively connected to a second circuit, and
the device further comprises an AND circuit configured to receive the output signal and including an output terminal connected to a third circuit that controls the second circuit.

8. The device according to claim 1, further comprising a fourth circuit configured to change the magnitude of the first voltage at the second timing, wherein
if the second voltage continuously increases in the first period, the second voltage continuously decreases in a third period subsequent to the first period, and if the second voltage continuously decreases in the first period, the second voltage continuously increases in the third period,
the second voltage becoming equal in magnitude to the changed first voltage at a third timing in the third period,
the first circuit being configured to change the signal to be output if a fourth timing at which the output signal is switched is out of a fourth period including the third timing, and
the fourth timing being different from the second timing.

9. The device according to claim 1, further comprising a second comparator including a third input terminal and a fourth input terminal, and being configured to receive a third voltage at the third input terminal and to receive at the fourth input terminal a fourth voltage that continuously increases or decreases in the first period, the fourth voltage being equal in magnitude to the third voltage at the first timing,
the first circuit being configured to change the signal to be output, if a fifth timing at which an output signal from the second comparator is switched is out of a fifth period including the first timing.

10. A movable body system comprising:
the semiconductor device recited in claim 1;
a second circuit selectively connected to the second input terminal; and
a third circuit configured to control the second circuit based on the output signal from the comparator.

11. A semiconductor device comprising:
a comparator including a first input terminal and a second input terminal, and being configured to receive a first voltage at the first input terminal and to receive at the second input terminal a second voltage that continuously increases or decreases in a first period, the second voltage being equal in magnitude to the first voltage at a first timing in the first period; and
a first circuit configured to change a signal to be output, if a second timing at which an output signal from the comparator is switched is within a second period including the first timing.

12. A semiconductor device comprising:
a comparator including a first input terminal and a second input terminal, and being configured to receive a first voltage at the first input terminal and to receive at the second input terminal a second voltage that continuously increases or decreases in a first period; and
a first circuit configured to output a signal indicating a magnitude of the first voltage based on a timing at which an output signal from the comparator is switched.

13. The device according to claim 12, wherein the first circuit measures the timing based on a count of periods of a clock signal.

14. The device according to claim 12, wherein the second voltage has a triangular waveform or a CR charging waveform.
